(19) United States
(12) Patent Application Publication
(10) Pub. No.: US 2023/0257604 A1
(43) Pub. Date: Aug. 17, 2023

(54) IMAGE RECORDING METHOD

(71) Applicant: FUJIFILM CORPORATION, Tokyo (JP)

(72) Inventors: Yusuke FUJII, Santa Clara, CA (US); Kazuhiro YOKOI, Santa Clara, CA (US); Yohei TAKAHASHI, Santa Clara, CA (US)

(21) Appl. No.: 18/306,242

(22) Filed: Apr. 25, 2023

Related U.S. Application Data
(63) Continuation of application No. PCT/JP2021/038650, filed on Oct. 19, 2021.
(60) Provisional application No. 63/105,913, filed on Oct. 27, 2020.

(51) Int. Cl. C09D 11/101; B41M 5/42

(52) U.S. Cl. CPC C09D 11/101; B41M 5/426

(57) ABSTRACT

An image recording method includes applying a conductive ink onto a base material by using an ink jet recording method and performing ultraviolet irradiation on the conductive ink applied onto the base material to form a conductive layer, in which a content of a liquid component of the conductive ink at a time when the ultraviolet irradiation begins is 5% by mass or more with respect to a content of the liquid component of the conductive ink at a time when the conductive ink is applied onto the base material.

### CROSS-REFERENCE TO RELATED APPLICATION

This application is a Continuation of International Application No. PCT/JP2021/038650, filed Oct. 19, 2021, which claims priority to U.S. Provisional Application No. 63/105,913, filed Oct. 27, 2020. Each of the above applications is hereby expressly incorporated by reference, in its entirety, into the present application.

### BACKGROUND OF THE INVENTION

### 1. Field of the Invention

The present disclosure relates to an image recording method.

### 2. Description of the Related Art

In a print substrate, sometimes noise such as electromagnetic wave noise or electrostatic noise is a problem. In the related art, a method of forming a conductive layer by thermal sintering using a silver particle ink is known.

For example, JP2014-529875A describes a method of preparing a conductive network of sintered silver including (a) step of preparing a conductive ink containing a silver compound and a binder, (b) step of depositing the conductive ink on a base material and irradiating the conductive ink with an external energy source to dry the deposited conductive ink, and (c) step of irradiating the dried conductive ink with an external energy source to decompose the silver compound into a silver element and sintering the silver element to make a conductive network. Furthermore, U.S. Ser. No. 10/597,547B describes an ink composition containing a silver complex.

WO2020/094583A describes a method of manufacturing a semiconductor package in which at least a part of the package is covered with an electromagnetic interference shielding layer.

### SUMMARY OF THE INVENTION

In a case where an image is formed on a base material by using a conductive ink, the improvement of image quality is required.

The present disclosure has been made in view of such circumstances, and an object to be achieved by one embodiment of the present invention is to provide an image recording method capable of recording an image with high image quality.

The present disclosure includes the following aspects.

<1> An image recording method including a step of applying a conductive ink onto a base material by using an ink jet recording method; and a step of performing ultraviolet irradiation on the conductive ink applied onto the base material to form a conductive layer, in which a content of a liquid component of the conductive ink at a time when the ultraviolet irradiation has begun is 5% by mass or more with respect to a content of the liquid component of the conductive ink at a time when the conductive ink has been applied onto the base material.

<2> The image recording method described in <1>, in which the conductive ink contains a metal salt or a metal complex.

<3> The image recording method described in <2>, in which the metal complex is a metal complex having a structure derived from at least one compound selected from the group consisting of an ammonium carbamate compound, an ammonium carbonate compound, an amine, and a carboxylic acid having 8 to 20 carbon atoms, and the metal salt is a metal carboxylate.

<4> The image recording method described in any one of <1> to <3>, in which a time from a time when the conductive ink has been landed on the base material to a time when the ultraviolet irradiation begins is 60 seconds or less.

<5> The image recording method described in any one of <1> to <4>, in which a time from a time when the conductive ink has been landed on the base material to a time when the ultraviolet irradiation begins is 10 seconds or less.

<6> The image recording method described in any one of <1> to <5>, in which a lamination step is performed one or more cycles, the lamination step including a step of applying a conductive ink onto the conductive layer by using an ink jet recording method and a step of performing ultraviolet irradiation on the conductive ink applied onto the conductive layer to form a conductive layer, and an average thickness of each conductive layer is 1.5 m or less.

<7> The image recording method described in <6>, in which the ultraviolet irradiation is performed whenever the step of applying a conductive ink is performed once.

<8> The image recording method described in any one of <1> to <7>, further including a step of applying an insulating ink onto a base material by using an ink jet recording method, a dispenser coating method, or a spray coating method and curing the insulating ink to form an insulating layer, in which the step of applying a conductive ink is a step of applying a conductive ink onto the insulating layer.

<9> The image recording method described in any one of <1> to <8>, in which the ultraviolet is light having a peak wavelength of 400 nm or less.

<10> The image recording method described in any one of <1> to <9>, in which the base material is a base material for a print substrate.

According to an embodiment of the present invention, there is provided an image recording method capable of recording an image with high image quality.

### DESCRIPTION OF THE PREFERRED EMBODIMENTS

Hereinafter, the image recording method of the present disclosure will be specifically described.

In the present specification, a range of numerical values described using “to” means a range including numerical values described before and after “to” as a minimum value and a maximum value, respectively.

Regarding the ranges of numerical values described stepwise in the present specification, the upper limit or the lower limit described in a certain range of numerical values may be replaced with the upper limit or the lower limit of another range of numerical values described stepwise. In addition, in the ranges of numerical values described in the present specification, the upper limit or the lower limit described in a certain range of numerical values may be replaced with the value shown in Examples.

In the present specification, in a case where there is a plurality of substances in a composition that corresponds to each component of the composition, unless otherwise specified, the amount of each component of the composition means the total amount of the plurality of substances present in the composition.

In the present specification, a combination of two or more preferred embodiments is a more preferred embodiment.

In the present specification, the term “step” includes not only an independent step but also a step which is not clearly distinguished from another step as long as the intended purpose of the step is achieved.

In the present specification, “image” means general films, and “image recording” means the formation of an image (that is, a film). In the present specification, the concept of “image” also includes a solid image.

[Image Recording Method]

The image recording method of the present disclosure includes a step of applying a conductive ink onto a base material by using an ink jet recording method and a step of performing ultraviolet irradiation on the conductive ink applied onto the base material to form a conductive layer, in which a content of a liquid component of the conductive ink at a time when the ultraviolet irradiation has begun is 5% by mass or more with respect to a content of the liquid component of the conductive ink at a time when the conductive ink has been applied onto the base material. Using the image recording method of the present disclosure makes it possible to record an image with high image quality. The reason is assumed to be as below.

In the image recording method of the present disclosure, the content of a liquid component of the conductive ink at a time when the ultraviolet irradiation has begun is 5% by mass or more with respect to the content of the liquid component of the conductive ink at a time when the conductive ink has been applied onto the base material. That is, in the image recording method of the present disclosure, in a state where the liquid component remains in the conductive ink, ultraviolet irradiation is carried out to sinter the components contained in the conductive ink. Presumably, because sintering is performed before the conductive ink wets and spreads on the base material, an image with high image quality could be recorded.

For example, JP2014-529875A describes a method of heating a conductive ink at 120° C. or 130° C. for 30 minutes and then performing ultraviolet irradiation. Presumably, in the method described in JP2014-529875A, at a time when the ultraviolet irradiation has begun, substantially no liquid component may remain in the conductive ink.

U.S. Ser. No. 10/597,547B describes an ink composition containing a silver complex. WO2020/094583A describes a method of manufacturing a semiconductor package in which at least a part of the package is covered with an electromagnetic interference shielding layer. However, the above documents do not have description focusing on the content of a liquid component of a conductive ink at a time when ultraviolet irradiation has begun.

<Conductive Ink Applying Step>

The image recording method of the present disclosure includes a step of applying a conductive ink onto a base material by using an ink jet recording method (hereinafter, called “conductive ink applying step”).

(Base Material)

The material of the base material is not particularly limited, and can be selected depending on the purpose. Specifically, examples of the material of the base material include synthetic resins such as polyimide, polyethylene terephthalate, polybutylene terephthalate, polytrimethylene terephthalate, polyethylene naphthalate, polybutylene naphthalate, polycarbonate, polyurethane, polyethylene, polypropylene, polyvinyl chloride, polystyrene, polyvinyl acetate, an acrylic resin, an acrylonitrile styrene resin (AS resin), an acrylonitrile-butadiene-styrene copolymer (ABS resin), triacetyl cellulose, polyamide, polyacetal, polyphenylene sulfide, polysulfone, an epoxy resin, a glass epoxy resin, a melamine resin, a phenol resin, a urea resin, an alkyd resin, a fluororesin, and polylactic acid; inorganic materials such as copper, steel, aluminum, silicon, soda glass, alkali-free glass, and indium tin oxide (ITO); and papers such as base paper, art paper, coated paper, cast coated paper, resin coated paper, and synthetic paper. The base material may be composed of one layer or two or more layers. In a case where the base material is composed of two or more layers, two or more base materials made of different materials may be laminated.

The base material is preferably in the form of a sheet or film. The thickness of the base material is preferably 20 μm to 2,000 μm.

The base material may have an ink receiving layer. The thickness of the ink receiving layer is preferably 1 μm to 20 μm. In a case where the thickness of the ink receiving layer is 1 μm to 20 μm, the ink receiving layer can be more stably maintained. The ink receiving layer is a coating layer formed on the base material to absorb and fix ink.

The base material may be subjected to a pretreatment before the application of the conductive ink. Examples of the pretreatment include known methods such as an ozone treatment, a plasma treatment, a corona treatment, a primer treatment, and a roughening treatment.

The base material may be a base material for a print substrate. A print substrate can be prepared by applying the insulating ink, which will be described later, onto a base material to form an insulating layer, and then applying a conductive ink onto the insulating layer to record an image to be a wiring pattern. Furthermore, a print substrate may be prepared by mounting an electronic component such as a chip on a base material, applying an insulating ink onto the mounted electronic component to form an insulating layer, and then applying a conductive ink onto the insulating layer to form a conductive layer.

An electromagnetic shield can be prepared by applying an insulating ink onto a base material to form an insulating layer, and then applying a conductive ink onto the insulating layer to cover the entire surface of the insulating layer with a conductive layer.

(Ink Jet Recording Method)

The ink jet recording method may be any of an electric charge control method of jetting an ink by using electrostatic attraction force, a drop-on-demand method using the vibration pressure of a piezo element (pressure pulse method), an acoustic ink jet method of jetting an ink by using radiation pressure by means of converting electric signals into acoustic beams and irradiating the ink with the acoustic beams, and a thermal ink jet (Bubble Jet (registered trademark)) method of forming bubbles by heating an ink and using the generated pressure.

As the ink jet recording method, particularly, it is possible to effectively use the method described in JP1979-59936A (JP-S54-59936A), which is an ink jet recording method of causing an ink to experience a rapid volume change by the action of thermal energy and jetting the ink from a nozzle by using the acting force resulting from the change of state.

Regarding the ink jet recording method, the method described in paragraphs “0093” to “0105” of JP2003-306623A can also be referred to.

Examples of ink jet heads used in the ink jet recording method include ink jet heads for a shuttle method of using short serial heads that are caused to scan a base material in a width direction of the base material to perform recording and ink jet heads for a line method of using line heads that each consist of recording elements arranged for the entire area of each side of a base material.

In the line method, by causing the base material to be scanned in a direction intersecting with the arrangement direction of the recording elements, a pattern can be formed on the entire surface of the base material. Therefore, this method does not require a transport system such as a carriage that moves short heads for scanning.

Furthermore, in the line method, complicated scanning control for moving a carriage and a base material is not necessary, and only a base material moves. Therefore, the recording speed can be further increased in the line method than in the shuttle method.

The liquid droplet volume of the insulating ink jetted from the ink jet head is preferably 1 pL (picoliter) to 100 pL, more preferably 3 pL to 80 pL, and even more preferably 3 pL to 20 pL.

(Temperature of Base Material at the Time of Applying Ink)

In the conductive ink applying step, at the time of applying the conductive ink, the temperature of the base material is preferably 20° C. to 120° C., and more preferably 28° C. to 80° C. In a case where the temperature of the base material is 20° C. to 120° C., the residual amount of the liquid component, which will be described later, can be 5% by mass or more.

(Conductive Ink)

In the present disclosure, the conductive ink means an ink for forming a conductive layer having conductivity. “Conductivity” means properties of having a volume resistivity less than 10⁸ Ωcm. The conductive layer may be formed on the entire surface of the base material or may be formed on a part of the base material. In a case where the conductive layer is formed on a part of the base material, the conductive layer may be in the form of a line.

The conductive ink is preferably an ink containing metal particles (hereinafter, also called “metal particle ink”), an ink containing a metal complex (hereinafter, also called “metal complex ink”), or an ink containing a metal salt (hereinafter, also called “metal salt ink”), and more preferably a metal salt ink or a metal complex ink.

<<Metal Particle Ink>>

The metal particle ink is, for example, an ink composition obtained by dispersing metal particles in a dispersion medium.

—Metal Particles—

Examples of the metal constituting the metal particles include particles of a base metal and a noble metal. Examples of the base metal include nickel, titanium, cobalt, copper, chromium, manganese, iron, zirconium, tin, tungsten, molybdenum, and vanadium. Examples of the noble metal include gold, silver, platinum, palladium, iridium, osmium, ruthenium, rhodium, rhenium, and alloys containing these metals. Among these, from the viewpoint of conductivity, the metal constituting the metal particles preferably includes at least one metal selected from the group consisting of silver, gold, platinum, nickel, palladium, and copper, and more preferably includes silver.

The average particle diameter of the metal particles is not particularly limited, but is preferably 10 nm to 500 nm, and more preferably 10 nm to 200 nm. In a case where the average particle diameter is in the above range, the baking temperature of the metal particles is lowered, which improves the process suitability for preparing the conductive ink film. Particularly, in a case where the metal particle ink is applied using a spray method or an ink jet recording method, jettability is improved, which tends to improve pattern forming properties and film thickness uniformity of the conductive ink film. The average particle diameter mentioned herein means the average of primary particle diameters of the metal particles (average primary particle diameter).

The average particle diameter of the metal particles is measured by a laser diffraction/scattering method. The average particle diameter of the metal particles is, for example, a value determined by measuring a 50% cumulative volume-based diameter (D50) three times and calculating the average of D50 measured three times. The average particle diameter of the metal particles can be measured using a laser diffraction/scattering-type particle size distribution analyzer (trade name “LA-960”, manufactured by Horiba, Ltd.).

As necessary, the metal particle ink may contain metal particles having an average particle diameter of 500 nm or more. In a case where the metal particle ink contains metal particles having an average particle diameter of 500 nm or more, the nm-sized metal particles lower the melting point around the m-sized metal particles, which makes it possible to bond the conductive ink film.

In the metal particle ink, the content of the metal particles with respect to the total amount of the metal particle ink is preferably 10% by mass to 90% by mass, and more preferably 20% by mass to 50% by mass. In a case where the content of the metal particles is 10% by mass or more, the surface resistivity is further reduced. In a case where the content of the metal particles is 90% by mass or less, jettability is improved in a case where the metal particle ink is applied using an ink jet recording method.

In addition to the metal particles, the metal particle ink may contain, for example, a dispersant, a resin, a dispersion medium, a thickener, and a surface tension adjuster.

—Dispersant—

The metal particle ink may contain a dispersant that adheres to at least a part of the surface of the metal particles. The dispersant substantially constitutes metal colloidal particles, together with the metal particles. The dispersant has an action of coating the metal particles to improve the dispersibility of the metal particles and prevent aggregation. The dispersant is preferably an organic compound capable of forming metal colloidal particles. From the viewpoint of conductivity and dispersion stability, the dispersant is preferably an amine, a carboxylic acid, an alcohol, or a resin dispersant.

The metal particle ink may contain one dispersant or two or more dispersants.

Examples of the amine include saturated or unsaturated aliphatic amines. Among these, an aliphatic amine having 4 to 8 carbon atoms is preferable as the amine. The aliphatic amine having 4 to 8 carbon atoms may be linear or branched, or may have a ring structure.

Examples of the aliphatic amine include butylamine, normal pentylamine, isopentylamine, hexylamine, 2-ethylhexylamine, and octylamine.

Examples of the amine having an alicyclic structure include cycloalkylamines such as cyclopentylamine and cyclohexylamine.

Examples of an aromatic amine include aniline.

The amine may have a functional group other than the amino group. Examples of the functional group other than an amino group include a hydroxy group, a carboxy group, an alkoxy group, a carbonyl group, an ester group, and a mercapto group.

Examples of the carboxylic acid include formic acid, oxalic acid, acetic acid, hexanoic acid, acrylic acid, octylic acid, oleic acid, tianshic acid, ricinoleic acid, gallic acid, and salicylic acid. The carboxy group which is a part of the carboxylic acid may form a salt with a metal ion. The salt may be formed of one metal ion or two or more metal ions.

The carboxylic acid may have a functional group other than the carboxy group. Examples of the functional group other than the carboxy group include an amino group, a hydroxy group, an alkoxy group, a carbonyl group, an ester group, and a mercapto group.

Examples of the alcohol include a terpene-based alcohol, an allyl alcohol, and an oleyl alcohol. The alcohol is likely to be coordinated with the surface of the metal particles and can suppress aggregation of the metal particles.

Examples of the resin dispersant include a dispersant that has a nonionic group as a hydrophilic group and can be homogeneously dissolved in a solvent. Examples of the resin dispersant include polyvinylpyrrolidone, polyethylene glycol, a polyethylene glycol-polypropylene glycol copolymer, polyvinyl alcohol, polyallylamine, and a polyvinyl alcohol-polyvinyl acetate copolymer. The molecular weight of the resin dispersant is preferably 1,000 to 50,000, and more preferably 1,000 to 30,000, in terms of a weight-average molecular weight.

In the metal particle ink, the content of the dispersant with respect to the total amount of the metal particle ink is preferably 0.5% by mass to 50% by mass, and more preferably 1% by mass to 30% by mass.

—Dispersion Medium—

It is preferable that the metal particle ink contain a dispersion medium. The type of dispersion medium is not particularly limited, and examples thereof include a hydrocarbon, an alcohol, and water.

The metal particle ink may contain one dispersion medium or two or more dispersion media. It is preferable that the dispersion medium contained in the metal particle ink be volatile. The boiling point of the dispersion medium is preferably 50° C. to 250° C., more preferably 70° C. to 220° C., and even more preferably 80° C. to 200° C. In a case where the boiling point of the dispersion medium is 50° C. to 250° C., the stability and baking properties of the metal particle ink tend to be simultaneously achieved.

Examples of the hydrocarbon include an aliphatic hydrocarbon and an aromatic hydrocarbon.

Examples of the aliphatic hydrocarbon include a saturated or unsaturated aliphatic hydrocarbon such as tetradecane, octadecane, heptamethylnonane, tetramethylpentadecane, hexane, heptane, octane, nonane, decane, tridecane, methylpentane, normal paraffin, or isoparaffin.

Examples of the aromatic hydrocarbon include toluene and xylene.

Examples of the alcohol include an aliphatic alcohol and an alicyclic alcohol. In a case where an alcohol is used as the dispersion medium, the dispersant is preferably an amine or a carboxylic acid.

Examples of the aliphatic alcohol include a saturated or unsaturated aliphatic alcohol having 6 to 20 carbon atoms that may contain an ether bond in a chain, such as heptanol, octanol (for example, 1-octanol, 2-octanol, 3-octanol, or the like), decanol (for example, 1-decanol or the like), lauryl alcohol, tetradecyl alcohol, cetyl alcohol, 2-ethyl-1-hexanol, octadecyl alcohol, hexadecenol, and oleyl alcohol.

Examples of the alicyclic alcohol include a cycloalkanol such as cyclohexanol; a terpene alcohol such as terpineol (including a, 3, and 7 isomers, or any mixture of these) or dihydroterpineol; myrtenol, menthol, carveol, perillyl alcohol, pinocarveol, sobrerol, and verbenol.

The dispersion medium may be water. From the viewpoint of adjusting physical properties such as viscosity, surface tension, and volatility, the dispersion medium may be a mixed solvent of water and another solvent. Another solvent to be mixed with water is preferably an alcohol. The alcohol used together with water is preferably an alcohol that is miscible with water and has a boiling point of 130° C. or lower. Examples of the alcohol include 1-propanol, 2-propanol, 1-butanol, 2-butanol, tert-butanol, 1-pentanol, ethylene glycol monomethyl ether, ethylene glycol monoethyl ether, ethylene glycol monopropyl ether, propylene glycol monomethyl ether.

In the metal particle ink, the content of the dispersion medium is preferably 1% by mass to 50% by mass with respect to the total amount of the metal particle ink. In a case where the content of the dispersion medium is 1% by mass to 50% by mass, the metal particle ink can obtain sufficient conductivity as a conductive ink. The content of the dispersion medium is more preferably 10% by mass to 45% by mass, and even more preferably 20% by mass to 40% by mass.

—Resin—

The metal particle ink may contain a resin. Examples of the resin include polyester, polyurethane, a melamine resin, an acrylic resin, a styrene-based resin, a polyether, and a terpene resin.

The metal particle ink may contain one resin or two or more resins.

In the metal particle ink, the content of the resin is preferably 0.1% by mass to 5% by mass with respect to the total amount of the metal particle ink.

—Thickener—

The metal particle ink may contain a thickener. Examples of the thickener include clay minerals such as clay, bentonite, and hectorite; cellulose derivatives such as methyl cellulose, carboxymethyl cellulose, hydroxyethyl cellulose, hydroxypropyl cellulose, and hydroxypropyl methyl cellulose; and polysaccharides such as xanthan gum and guar gum.

The metal particle ink may contain one thickener or two or more thickeners.

In the metal particle ink, the content of the thickener is preferably 0.1% by mass to 5% by mass with respect to the total amount of the metal particle ink.

—Surfactant—

The metal particle ink may contain a surfactant. In a case where the metal particle ink contains a surfactant, a uniform conductive ink film is likely to be formed.

The surfactant may be any of an anionic surfactant, a cationic surfactant, and a nonionic surfactant. Among these, as the surfactant, a fluorine-based surfactant is preferable, because this surfactant makes it possible to adjust the surface tension even though the metal particle ink contains a small amount of such a surfactant. Furthermore, the surfactant is preferably a compound having a boiling point higher than 250° C.

The viscosity of the metal particle ink is not particularly limited. The viscosity of the metal particle ink may be 0.01 Pa·s to 5,000 Pa·s, and is preferably 0.1 Pa·s to 100 Pa·s. In a case where the metal particle ink is applied using a spray method or an ink jet recording method, the viscosity of the metal particle ink is preferably 1 mPa·s to 100 mPa·s, more preferably 2 mPa·s to 50 mPa·s, and even more preferably 3 mPa·s to 30 mPa·s.

The viscosity of the metal particle ink is a value measured at 25° C. by using a viscometer. The viscosity is measured, for example, using a VISCOMETER TV-22 type viscometer (manufactured by TOKISANGYO).

The surface tension of the metal particle ink is not particularly limited, and is preferably 20 mN/m to 45 mN/m and more preferably 25 mN/m to 40 mN/m.

The surface tension is a value measured at 25° C. by using a surface tensiometer.

The surface tension of the metal particle ink is measured using, for example, DY-700 (manufactured by Kyowa Interface Science Co., Ltd.).

—Manufacturing Method of Metal Particles—

The metal particles may be a commercially available product or may be manufactured by a known method. Examples of the manufacturing method of the metal particles include a wet reduction method, a vapor phase method, and a plasma method. Preferred examples of the manufacturing method of the metal particles include a wet reduction method capable of manufacturing metal particles having an average particle diameter of 200 nm or less and having a narrow particle size distribution. Examples of the manufacturing method of the metal particles by a wet reduction method include the method described in JP2017-37761A, WO2014-57633A and the like, the method including a step of mixing a metal salt with a reducing agent to obtain a complexing reaction solution and a step of heating the complexing reaction solution to reduce metal ions in the complexing reaction solution and to obtain a slurry of metal nanoparticles.

In manufacturing the metal particle ink, a heating treatment may be performed such that the content of each component contained in the metal particle ink is adjusted to be in a predetermined range. The heating treatment may be performed under reduced pressure or under normal pressure. In a case where the heating treatment is performed under normal pressure, the heating treatment may be performed in the atmosphere or in an inert gas atmosphere.

<<Metal Complex Ink>>

The metal complex ink is, for example, an ink composition obtained by dissolving a metal complex in a solvent.

—Metal Complex—

Examples of metals constituting the metal complex include silver, gold, aluminum, magnesium, tungsten, molybdenum, zinc, nickel, iron, platinum, tin, copper, and lead. Among these, from the viewpoint of conductivity, the metal constituting the metal complex preferably includes at least one metal selected from the group consisting of silver, gold, platinum, nickel, palladium, and copper, and more preferably includes silver.

The content of the metal contained in the metal complex ink with respect to the total amount of the metal complex ink is preferably 1% by mass to 40% by mass, more preferably 5% by mass to 30% by mass, and even more preferably 7% by mass to 20% by mass, in terms of the metal element.

The metal complex can be obtained, for example, by reacting a metal salt with a complexing agent. Examples of the manufacturing method of the metal complex include a method of adding a metal salt and a complexing agent to an organic solvent and stirring the mixture for a predetermined time. The stirring method is not particularly limited, and can be appropriately selected from known methods such as a stirring method using a stirrer, a stirring blade, or a mixer, and a method of applying ultrasonic waves.

Examples of the metal salt include a metal oxide, thiocyanate, sulfide, chloride, cyanide, cyanate, carbonate, acetate, nitrate, nitrite, sulfate, phosphate, perchlorate, tetrafluoroborate, an acetyl acetonate complex salt, and carboxylate.

Examples of the complexing agent include an amine, an ammonium carbamate compound, an ammonium carbonate compound, an ammonium bicarbonate compound, and a carboxylic acid. Among these, from the viewpoint of the conductivity and the stability of the metal complex, it is preferable that the complexing agent include at least one compound selected from the group consisting of an ammonium carbamate compound, an ammonium carbonate compound, an amine, and a carboxylic acid having 8 to 20 carbon atoms.

The metal complex has a structure derived from a complexing agent. It is preferable that the metal complex have a structure derived from at least one compound selected from the group consisting of an ammonium carbamate compound, an ammonium carbonate compound, an amine, and a carboxylic acid having 8 to 20 carbon atoms.

Examples of the amine as a complexing agent include ammonia, a primary amine, a secondary amine, a tertiary amine, and a polyamine.

Examples of the primary amine having a linear alkyl group include methylamine, ethylamine, 1-propylamine, n-butylamine, n-pentylamine, n-hexylamine, heptylamine, octylamine, nonylamine, n-decylamine, undecylamine, dodecylamine, tridecylamine, tetradecylamine, pentadecylamine, hexadecylamine, heptadecylamine, and octadecylamine.

Examples of the primary amine having a branched alkyl group include isopropylamine, sec-butylamine, tert-butylamine, isopentylamine, 2-ethylhexylamine, and tert-octylamine.

Examples of the primary amine having an alicyclic structure include cyclohexylamine and dicyclohexylamine.

Examples of the primary amine having a hydroxyalkyl group include ethanolamine, diethanolamine, triethanolamine, N-methylethanolamine, propanolamine, isopropanolamine, dipropanolamine, diisopropanolamine, tripropanolamine, and triisopropanolamine.

Examples of the primary amine having an aromatic ring include benzylamine, N,N-dimethylbenzylamine, phenylamine, diphenylamine, triphenylamine, aniline, N,N-dimethylaniline, N,N-dimethyl-p-toluidine, 4-aminopyridine, and 4-dimethylaminopyridine.

Examples of the secondary amine include dimethylamine, diethylamine, dipropylamine, dibutylamine, diphenylamine, dicyclopentylamine, and methylbutylamine.

Examples of the tertiary amine include trimethylamine, triethylamine, tripropylamine, and triphenylamine.

Examples of the polyamine include ethylenediamine, 1,3-diaminopropane, diethylenetriamine, triethylenetetramine, tetramethylenepentamine, hexamethylenediamine, tetraethylenepentamine, and a combination of these.

The amine is preferably an alkylamine, more preferably an alkylamine having 3 to 10 carbon atoms, and even more preferably a primary alkylamine having 4 to 10 carbon atoms.

The metal complex may be configured with one amine or two or more amines.

In reacting the metal salt with an amine, the ratio of the molar amount of the amine to the molar amount of the metal salt is preferably 1/1 to 15/1, and more preferably 1.5/1 to 6/1. In a case where the above ratio is within the above range, the complex formation reaction goes to completion, and a transparent solution is obtained.

Examples of the ammonium carbamate compound as a complexing agent include ammonium carbamate, methylammonium methylcarbamate, ethylammonium ethylcarbamate, 1-propylammonium 1-propylcarbamate, isopropylammonium isopropylcarbamate, butylammonium butylcarbamate, isobutylammonium isobutylcarbamate, amylammonium amylcarbamate, hexylammonium hexylcarbamate, heptylammonium heptylcarbamate, octylammonium octylcarbamate, 2-ethylhexylammonium 2-ethylhexylcarbamate, nonylammonium nonylcarbamate, and decylammonium decylcarbamate.

Examples of the ammonium carbonate compound as a complexing agent include ammonium carbonate, methylammonium carbonate, ethylammonium carbonate, 1-propylammonium carbonate, isopropylammonium carbonate, butylammonium carbonate, isobutylammonium carbonate, amylammonium carbonate, hexylammonium carbonate, heptylammonium carbonate, octylammonium carbonate, 2-ethylhexylammonium carbonate, nonylammonium carbonate, and decylammonium carbonate.

Examples of the ammonium bicarbonate compound as a complexing agent include ammonium bicarbonate, methylammonium bicarbonate, ethylammonium bicarbonate, 1-propylammonium bicarbonate, isopropylammonium bicarbonate, butylammonium bicarbonate, isobutylammonium bicarbonate, amylammonium bicarbonate, hexylammonium bicarbonate, heptylammonium bicarbonate, octylammonium bicarbonate, 2-ethylhexylammonium bicarbonate, nonylammonium bicarbonate, and decylammonium bicarbonate.

In reacting the metal salt with an ammonium carbamate compound, an ammonium carbonate compound, or an ammonium bicarbonate compound, the ratio of the molar amount of the ammonium carbamate compound, the ammonium carbonate compound, or the ammonium bicarbonate compound to the molar amount of the metal salt is preferably 0.01/1 to 1/1, and more preferably 0.05/1 to 0.6/1.

Examples of the carboxylic acid as a complexing agent include caproic acid, caprylic acid, pelargonic acid, 2-ethylhexanoic acid, capric acid, neodecanoic acid, undecanoic acid, lauric acid, myristic acid, palmitic acid, stearic acid, palmitoleic acid, oleic acid, linoleic acid, and linolenic acid. Among these, as the carboxylic acid, a carboxylic acid having 8 to 20 carbon atoms is preferable, and a carboxylic acid having 10 to 16 carbon atoms is more preferable.

In the metal complex ink, the content of the metal complex with respect to the total amount of the metal complex ink is preferably 10% by mass to 90% by mass, and more preferably 10% by mass to 40% by mass. In a case where the content of the metal complex is 10% by mass or more, the surface resistivity is further reduced. In a case where the content of the metal complex is 90% by mass or less, jettability is improved in a case where the metal complex ink is applied using an ink jet recording method.

—Solvent—

It is preferable that the metal complex ink contain a solvent. The solvent is not particularly limited as long as it can dissolve the component contained in the metal complex ink, such as the metal complex. From the viewpoint of ease of manufacturing, the boiling point of the solvent is preferably 30° C. to 300° C., more preferably 50° C. to 200° C., and even more preferably 50° C. to 150° C.

The content of the solvent in the metal complex ink ink is preferably set such that the concentration of metal ions with respect to the metal complex (the amount of the metal present as free ions with respect to 1 g of the metal complex) is 0.01 mmol/g to 3.6 mmol/g, and more preferably set such that the aforementioned concentration of metal ions is 0.05 mmol/g to 2 mmol/g. In a case where the concentration of metal ions is within the above range, the metal complex ink has excellent fluidity and can obtain conductivity.

Examples of the solvent include a hydrocarbon, a cyclic hydrocarbon, an aromatic hydrocarbon, a carbamate, an alkene, an amide, an ether, an ester, an alcohol, a terpene, a terpenoid, a thiol, a thioether, phosphine, and water. The metal complex ink may contain only one solvent or two or more solvents.

The hydrocarbon is preferably a linear or branched hydrocarbon having 6 to 20 carbon atoms. Examples of the hydrocarbon include pentane, hexane, heptane, octane, nonane, decane, undecane, dodecane, tridecane, tetradecane, pentadecane, hexadecane, octadecane, nonadecane, and icosane.

The cyclic hydrocarbon is preferably a cyclic hydrocarbon having 6 to 20 carbon atoms. The cyclic hydrocarbons can include, for example, cyclohexane, cycloheptane, cyclooctane, cyclononane, cyclodecane, and decalin.

Examples of the aromatic hydrocarbon include benzene, toluene, xylene, and tetraline.

The ether may be any of a linear ether, a branched ether, and a cyclic ether. Examples of the ether include diethyl ether, dipropyl ether, dibutyl ether, methyl-t-butyl ether, tetrahydrofuran, tetrahydropyrane, dihydropyrane, and 1,4-dioxane.

The alcohol may be any of a primary alcohol, a secondary alcohol, and a tertiary alcohol.

Examples of the alcohol include ethanol, 1-propanol, 2-propanol, 1-methoxy-2-propanol, 1-butanol, 2-butanol, 1-pentanol, 2-pentanol, 3-pentanol, 1-hexanol, 2-hexanol, 3-hexanol, 1-octanol, 2-octanol, 3-octanol, tetrahydrofurfuryl alcohol, cyclopentanol, terpineol, decanol, isodecyl alcohol, lauryl alcohol, isolauryl alcohol, myristyl alcohol, isomyristyl alcohol, cetyl alcohol (cetanol), isocetyl alcohol, stearyl alcohol, isostearyl alcohol, oleyl alcohol, isooleyl alcohol, linoleyl alcohol, isolinoleyl alcohol, palmityl alcohol, isopalmityl alcohol, icosyl alcohol, and isoicosyl alcohol.

Examples of the ketone include acetone, methyl ethyl ketone, methyl isobutyl ketone, and cyclohexanone.

Examples of the ester include methyl acetate, ethyl acetate, isopropyl acetate, butyl acetate, isobutyl acetate, sec-butyl acetate, methoxybutyl acetate, ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, propylene glycol monomethyl ether acetate, propylene glycol monoethyl ether acetate, propylene glycol monobutyl ether acetate, dipropylene glycol monomethyl ether acetate, dipropylene glycol monoethyl ether acetate, dipropylene glycol monobutyl ether acetate, and 3-methoxybutyl acetate.

Terpene is a hydrocarbon represented by the composition (C₅H₈)ₙ. Examples of the terpene include a monoterpene (C₁₀H₁₆), a sesquiterpene (C₁₅H₂₄), and a diterpene (C₂₀H₃₂). Specifically examples thereof include α-pinene, β-pinene, dipentene, limonene, myrcene, alloocimene, ocimene, α-phellandrene, α-terpinene, γ-terpinene, and terpinolene.

Examples of the terpenoid include myrcene, ocimene, geraniol, nerol, linalool, citronellol, citral, menthene, limonene, dipentene, terpinolene, terpinene, phellandrene, sylvestrene, piperitol, terpineol, menthenemonol, isopregol, perillaldehyde, piperitone, dihydrocarvone, carvone, pinol, ascaridole, sabinene, carene, pinene, bornene, fenchene, camphene, and carveol.

—Reducing Agent—

The metal complex ink may contain a reducing agent. In a case where the metal complex ink contains a reducing agent, the reduction of the metal complex into a metal is facilitated.

Examples of the reducing agent include a borohydride metal salt, an aluminum hydride salt, an amine, an alcohol, an organic acid, reduced sugar, a sugar alcohol, sodium sulfite, a hydrazine compound, dextrin, hydroquinone, hydroxylamine, ethylene glycol, glutathione, and an oxime compound.

The reducing agent may be the oxime compound described in JP2014-516463A. Examples of the oxime compound include acetone oxime, cyclohexanone oxime, 2-butanone oxime, 2,3-butanedione monoxime, dimethyl glyoxime, methyl acetoacetate monoxime, methyl pyruvate monoxime, benzaldehyde oxime, 1-indanone oxime, 2-adamantanone oxime, 2-methylbenzamide oxime, 3-methylbenzamide oxime, 4-methylbenzamide oxime, 3-aminobenzamide oxime, 4-aminobenzamide oxime, acetophenone oxime, benzamide oxime, and pinacolone oxime.

The metal complex ink may contain one reducing agent or two or more reducing agents.

The content of the reducing agent in the metal complex ink is not particularly limited. The content of the reducing agent with respect to the total amount of the metal complex ink is preferably 0.1% by mass to 20% by mass, more preferably 0.3% by mass to 10% by mass, and even more preferably 1% by mass to 5% by mass.

—Resin—

The metal complex ink may contain a resin. In a case where the metal complex ink contains a resin, the adhesiveness of the metal complex ink to the base material is improved.

Examples of the resin include polyester, polyethylene, polypropylene, polyacetal, polyolefin, polycarbonate, polyamide, a fluororesin, a silicone resin, ethyl cellulose, hydroxyethyl cellulose, rosin, an acrylic resin, polyvinyl chloride, polysulfone, polyvinylpyrrolidone, polyvinyl alcohol, a polyvinyl-based resin, polyacrylonitrile, polysulfide, polyamideimide, polyether, polyarylate, polyether ether ketone, polyurethane, an epoxy resin, a vinyl ester resin, a phenol resin, a melamine resin, and a urea resin.

The metal complex ink may contain one resin or two or more resins.

—Additive—

As long as the effects of the present disclosure are not reduced, the metal complex ink may further contain additives such as an inorganic salt, an organic salt, an inorganic oxide such as silica, a surface conditioner, a wetting agent, a crosslinking agent, an antioxidant, a rust inhibitor, a heat-resistant stabilizer, a surfactant, a plasticizer, a curing agent, a thickener, and a silane coupling agent. In the metal complex ink, the total content of additives is preferably 20% by mass or less with respect to the total amount of the metal complex ink.

The viscosity of the metal complex ink is not particularly limited. The viscosity of the metal complex ink may be 0.01 Pa·s to 5,000 Pa·s, and is preferably 0.1 Pa·s to 100 Pa·s. In a case where the metal complex ink is applied using a spray method or an ink jet recording method, the viscosity of the metal complex ink is preferably 1 mPa·s to 100 mPa·s, more preferably 2 mPa·s to 50 mPa·s, and even more preferably 3 mPa·s to 30 mPa·s.

The viscosity of the metal complex ink is a value measured at 25° C. by using a viscometer. The viscosity is measured, for example, using a VISCOMETER TV-22 type viscometer (manufactured by TOKISANGYO).

The surface tension of the metal complex ink is not particularly limited, and is preferably 20 mN/m to 45 mN/m and more preferably 25 mN/m to 35 mN/m. The surface tension is a value measured at 25° C. by using a surface tensiometer.

The surface tension of the metal complex ink is measured using, for example, DY-700 (manufactured by Kyowa Interface Science Co., Ltd.).

<<Metal Salt Ink>>

The metal salt ink is, for example, an ink composition obtained by dissolving a metal salt in a solvent.

—Metal Salt—

Examples of metals constituting the metal salt include silver, gold, aluminum, magnesium, tungsten, molybdenum, zinc, nickel, iron, platinum, tin, copper, and lead. Among these, from the viewpoint of conductivity, the metal constituting the metal salt preferably includes at least one metal selected from the group consisting of silver, gold, platinum, nickel, palladium, and copper, and more preferably includes silver.

The content of the metal contained in the metal salt ink with respect to the total amount of the metal salt ink is preferably 1% by mass to 40% by mass, more preferably 5% by mass to 30% by mass, and even more preferably 7% by mass to 20% by mass, in terms of the metal element.

In the metal salt ink, the content of the metal salt with respect to the total amount of the metal salt ink is preferably 10% by mass to 90% by mass, and more preferably 10% by mass to 60% by mass. In a case where the content of the metal salt is 10% by mass or more, the surface resistivity is further reduced. In a case where the content of the metal salt is 90% by mass or less, jettability is improved in a case where the metal salt ink is applied using a spray method or an ink jet recording method.

Examples of the metal salt include benzoate, halide, carbonate, citrate, iodate, nitrite, nitrate, acetate, phosphate, sulfate, sulfide, trifluoroacetate, and carboxylate of a metal. It should be noted that two or more salts may be combined.

From the viewpoint of conductivity and storage stability, the metal salt is preferably a metal carboxylate. The carboxylic acid forming the carboxylate is preferably at least one compound selected from the group consisting of formic acid and a carboxylic acid having 1 to 30 carbon atoms, and more preferably a carboxylic acid having 8 to 20 carbon atoms, and even more preferably a fatty acid having 8 to 20 carbon atoms. The fatty acid may be linear or branched or may have a substituent.

Examples of the linear fatty acid include acetic acid, propionic acid, butyric acid, valeric acid, pentanoic acid, hexanoic acid, heptanoic acid, behenic acid, oleic acid, octanoic acid, nonanoic acid, decanoic acid, caproic acid, enanthic acid, caprylic acid, pelargonic acid, capric acid, and undecanoic acid.

Examples of the branched fatty acid include isobutyric acid, isovaleric acid, ethylhexanoic acid, neodecanoic acid, pivalic acid, 2-methylpentanoic acid, 3-methylpentanoic acid, 4-methylpentanoic acid, 2,2-dimethylbutanoic acid, 2,3-dimethylbutanoic acid, 3,3-dimethylbutanoic acid, and 2-ethylbutanoic acid.

Examples of the carboxylic acid having a substituent include hexafluoroacetylacetonate, hydroangelate, 3-hydroxybutyric acid, 2-methyl-3-hydroxybutyric acid, 3-methoxybutyric acid, acetonedicarboxylic acid, 3-hydroxyglutaric acid, 2-methyl-3-hydroxyglutaric acid, and 2,2,4,4-hydroxyglutaric acid.

The metal salt may be a commercially available product or may be manufactured by a known method. For example, a silver salt is manufactured by the following method.

First, a silver compound (for example, silver acetate) functioning as a silver supply source and formic acid or a fatty acid having 1 to 30 carbon atoms in the same quantity as the molar equivalent of the silver compound are added to an organic solvent such as ethanol. The mixture is stirred for a predetermined time by using an ultrasonic stirrer, and the formed precipitate is washed with ethanol and decanted. All of these steps can be performed at room temperature (25° C.). The mixing ratio of the silver compound and the formic acid or fatty acid having 1 to 30 carbon atoms is preferably 1:2 to 2:1, and more preferably 1:1, in terms of molar ratio.

The metal salt ink may contain a solvent, a reducing agent, a resin, and additives. Preferred aspects of the solvent, reducing agent, resin, and additives are the same as the preferred aspects of the solvent, reducing agent, resin, and additives which may be contained in the metal complex ink.

The viscosity of the metal salt ink is not particularly limited. The viscosity of the metal salt ink may be 0.01 Pa·s to 5,000 Pa·s, and is preferably 0.1 Pa·s to 100 Pa·s. In a case where the metal salt ink is applied using a spray method or an ink jet recording method, the viscosity of the metal salt ink is preferably 1 mPa·s to 100 mPa·s, more preferably 2 mPa·s to 50 mPa·s, and even more preferably 3 mPa·s to 30 mPa·s.

The viscosity of the metal salt ink is a value measured at 25° C. by using a viscometer. The viscosity is measured, for example, using a VISCOMETER TV-22 type viscometer (manufactured by TOKISANGYO).

The surface tension of the metal salt ink is not particularly limited, and is preferably 20 mN/m to 45 mN/m and more preferably 25 mN/m to 35 mN/m. The surface tension is a value measured at 25° C. by using a surface tensiometer.

The surface tension of the metal salt ink is measured using, for example, DY-700 (manufactured by Kyowa Interface Science Co., Ltd.).

It is preferable that the conductive ink used in the image recording method of the present disclosure contain a metal complex or a metal salt. The metal complex is preferably a metal complex having a structure derived from at least one compound selected from the group consisting of an ammonium carbamate compound, an ammonium carbonate compound, an amine, and a carboxylic acid having 8 to 20 carbon atoms, and the metal salt is preferably a metal carboxylate.

<Conductive Layer Forming Step>

The image recording method of the present disclosure includes a step of performing ultraviolet irradiation on the conductive ink applied onto the base material to form a conductive layer (hereinafter, called “conductive layer forming step”).

In the image recording method of the present disclosure, the content of a liquid component of the conductive ink at a time when ultraviolet irradiation has begun is 5% by mass or more with respect to the content of the liquid component of the conductive ink at a time when the conductive ink has been applied onto the base material. Hereinafter, the content of the liquid component of the conductive ink at a time when the ultraviolet irradiation has begun with respect to the content of the liquid component of the conductive ink at a time when the conductive ink has been applied onto the base material will be called “residual amount of the liquid component”.

As will be described later, in a case where the ultraviolet irradiation is performed a plurality of times, the residual amount of the liquid component is calculated as the average of residual amounts of the liquid component at each point in time when the ultraviolet irradiation has begun.

The liquid component of the conductive ink means a component that can be volatilized by an external factor such as heat or light. Examples of the liquid component of the conductive ink include water and an organic solvent.

The residual amount of the liquid component is 5% by mass or more, preferably 20% by mass or more, and more preferably 50% by mass or more. In a case where the residual amount of the liquid component is 5% by mass or more, the conductive ink is cured before wetting and spreading on the base material. Therefore, an image with high image quality is obtained.

The upper limit of the residual amount of the liquid component is not particularly limited, and may be 100% by mass.

The content of the liquid component of the conductive ink at a time when the conductive ink has been applied onto the base material is obtained by calculating the content of the liquid component contained in the conductive ink stored in an ink tank of an ink jet recording device, immediately before the conductive ink is applied onto the base material. The content of the liquid component contained in the conductive ink can be calculated, for example, by the following method.

First, a certain amount of conductive ink is collected from the conductive ink stored in the ink tank and weighed. The measured weight is denoted by A1. Then, the weighed conductive ink is heated in an oven at 200° C. for 60 minutes. The solidified substance obtained by heating is weighed. The measured weight is denoted by A2. By the following equation, a content X of the liquid component contained in the conductive ink is calculated.

Content X of liquid component (% by mass)={(A1−A2)/A1}×100

The content of the liquid component of the conductive ink at a time when the ultraviolet irradiation has begun can be calculated, for example, by the following method.

First, as a base material, ink jet paper (trade name “KASSAI”, manufactured by FUJIFILM Corporation) is cut in an image size (2 cm×3 cm), and the cut base material is weighed. The measured weight is denoted by B1. The base material is set in an ink jet recording device, and in an environment of room temperature (23° C.), 1,000,000 droplets of the conductive ink are jetted at a liquid droplet volume of 10 pL without being subjected to ultraviolet irradiation. Within 3 seconds after the end of jetting, the base material to which the conductive ink is applied is weighed. The measured weight is denoted by B2. By the following equation, an amount Y of the conductive ink at a time when the conductive ink has been applied onto the base material is calculated.

Amount Y of conductive ink at point in time when conductive ink has been applied onto base material=B2−B1

Furthermore, as a base material, a base material actually used for image recording is cut in a certain size, and the cut base material is weighed. The measured weight is denoted by C1. The base material is set in an ink jet recording device, and under a certain temperature condition, 1,000,000 droplets of the conductive ink are jetted at a liquid droplet volume of 10 pL without being subjected to ultraviolet irradiation. After a certain period of time elapses from the end of jetting, the base material to which the conductive ink is applied is weighed. The measured weight is denoted by C2. In a case where ultraviolet irradiation is performed after a certain period of time elapses, by the following equation, an amount Z of the conductive ink at a time when the ultraviolet irradiation has begun is calculated.

Amount Z of conductive ink at point in time when ultraviolet irradiation has begun=C2−C1

By the following equation, a decrease of the liquid component at a time when the ultraviolet irradiation has begun is calculated.

Decrease of liquid component=Y−Z

By the following equation, the residual amount of the liquid component is calculated.

Residual amount of liquid component (% by mass)={(Y×X/100)−(Y−Z)}/(Y×X/100)×100

The peak wavelength of the ultraviolet is preferably 405 nm or less, more preferably 400 nm or less, and even more preferably 390 nm or less. The lower limit of the peak wavelength of the ultraviolet is not particularly limited, and is, for example, 200 nm.

In a case where the peak wavelength of the ultraviolet is 405 nm or less, the conductivity of the obtained image is improved.

The exposure amount during the ultraviolet irradiation is preferably 0.1 J/cm² to 1,000 J/cm², and more preferably 0.5 J/cm² to 100 J/cm². As will be described later, in a case where the ultraviolet irradiation is performed a plurality of times, the exposure amount means the sum of exposure amounts of the ultraviolet irradiation performed a plurality of times (total exposure amount).

As the light source for ultraviolet irradiation, a mercury lamp, a gas laser, and a solid-state laser are mainly used. A mercury lamp, a metal halide lamp, and an ultraviolet fluorescent lamp are widely known light sources. Being compact, highly efficient, low cost, and having a long life, UV-LED (light emitting diode) and UV-LD (laser diode) are promising light sources for ultraviolet irradiation. As the light source for ultraviolet irradiation, among these, a metal halide lamp, a high-pressure mercury lamp, a medium-pressure mercury lamp, a low-pressure mercury lamp, or UV-LED is preferable.

In the image recording method of the present disclosure, a time from a time when the conductive ink has been landed on the base material to a time when the ultraviolet irradiation begins (hereinafter, called “time A”) is preferably 150 seconds or less, more preferably 60 seconds or less, and even more preferably 10 seconds or less. In a case where the time A is 150 seconds or less, the conductive ink is cured before wetting and spreading on the base material, which improves the image quality of the obtained image. The lower limit of the time A is not particularly limited, and is, for example, 1 s.

<Lamination Step>

In the image recording method of the present disclosure, after the conductive ink is applied onto the base material, a conductive ink may be further applied. Hereinafter, a layer formed by applying the conductive ink once will be also called “conductive layer”, and layers formed by applying the conductive ink a plurality of times will be also called “whole conductive layer”.

In the image recording method of the present disclosure, ultraviolet irradiation may be performed after the conductive ink is applied onto the base material twice or more. In addition, in the image recording method of the present disclosure, ultraviolet irradiation may be performed after the conductive ink is applied once onto the base material, and a conductive ink may be further applied onto the formed conductive layer.

The image recording method of the present disclosure includes a step of applying a conductive ink onto a base material and a step of performing ultraviolet irradiation on the conductive ink applied onto the base material to form a conductive layer. In the image recording method of the present disclosure, it is preferable that a lamination step be performed one or more cycles, the lamination step including a step of applying a conductive ink onto the conductive layer by using an ink jet recording method and a step of performing ultraviolet irradiation on the conductive ink applied onto the conductive layer to additionally form a conductive layer.

Increasing the number of times the conductive ink is applied makes it possible to increase the thickness of the whole conductive layer.

In a case where conductive inks are applied twice or more, the types of conductive inks may be the same as or different from each other. From the viewpoint of manufacturing efficiency, it is preferable that the types of conductive inks be the same as each other. The same type of conductive inks means that the components contained in the conductive inks and the contents of the components are the same for all the conductive inks. The different types of conductive inks mean that at least either the components contained in the conductive inks or the contents of the components vary between the conductive inks.

The number of times the lamination step is performed is not particularly limited, and is appropriately adjusted depending on the thickness of the whole conductive layer to be formed. From the viewpoint of conductivity, the thickness of the whole conductive layer is preferably 0.1 m to 30 m, and more preferably 0.3 m to 15 m.

The thickness of the whole conductive layer is measured using a laser microscope (trade name “VK-X1000”, manufactured by KEYENCE CORPORATION).

The average thickness of each conductive layer is obtained by dividing the thickness of the whole conductive layer by the number of times the conductive layer is formed (that is, the number of times the conductive ink is applied).

In the image recording method of the present disclosure, the average thickness of each conductive layer is preferably 1.5 μm or less, and more preferably 1.2 μm or less.

In a case where the average thickness of each conductive layer is 1.5 μm or less, the conductivity is further improved.

In the lamination step, a step of applying a conductive ink onto the conductive layer by using an ink jet recording method may be performed a plurality of times, and then a step of performing ultraviolet irradiation on the conductive ink applied onto the conductive layer to additionally form a conductive layer may be performed.

From the viewpoint of image quality, conductivity, and adhesiveness, in the lamination step, it is preferable that a step of applying a conductive ink onto the conductive layer by using an ink jet recording method be performed once, and then a step of performing ultraviolet irradiation on the conductive ink applied onto the conductive layer to additionally form a conductive layer be performed. That is, it is preferable that the ultraviolet irradiation be performed whenever the step of applying a conductive ink is performed once.

<Baking Step>

The image recording method of the present disclosure may include a baking step of baking the conductive layer after the ultraviolet irradiation.

The baking temperature is preferably 250° C. or lower, more preferably 50° C. to 200° C., and even more preferably 80° C. to 150° C. The baking time is preferably 1 minute to 120 minutes, and more preferably 1 minute to 40 minutes. In a case where the baking temperature and the baking time are in the above ranges, it is possible to reduce the influence of base material deformation or the like caused by heat.

Particularly, in a case where the conductive ink contains a metal salt or metal particles, it is preferable to bake the conductive layer after the ultraviolet irradiation.

<Insulating Layer Forming Step>

It is preferable that the image recording method of the present disclosure include a step of applying an insulating ink onto a base material by using an ink jet recording method, a dispenser coating method, or a spray coating method and curing the insulating ink to form an insulating layer. Furthermore, the step of applying a conductive ink is preferably a step of applying a conductive ink onto the insulating layer.

From the viewpoint of making it possible to form a thin insulating ink film by applying once a small amount of insulating ink by means of jetting, it is preferable that the insulating ink be applied by an ink jet recording method. Details of the ink jet recording method are as described above.

The method of curing the insulating ink is not particularly limited, and examples thereof include a method of irradiating the insulating ink applied onto the base material with an active energy ray.

Examples of the active energy ray include ultraviolet rays, visible rays, and electron beams. Among these, ultraviolet rays (hereinafter, also called “UV”) are preferable.

The peak wavelength of the ultraviolet rays is preferably 200 nm to 405 nm, more preferably 250 nm to 400 nm, and even more preferably 300 nm to 400 nm.

The exposure amount during the active energy ray irradiation is preferably 100 mJ/cm² to 5,000 J/cm², and more preferably 300 mJ/cm² to 1,500 mJ/cm².

As the light source for ultraviolet irradiation, a mercury lamp, a gas laser, and a solid-state laser are mainly used. A mercury lamp, a metal halide lamp, and an ultraviolet fluorescent lamp are widely known light sources. Being compact, highly efficient, low cost, and having a long life, UV-LED (light emitting diode) and UV-LD (laser diode) are promising light sources for ultraviolet irradiation. As the light source for ultraviolet irradiation, among these, a metal halide lamp, a high-pressure mercury lamp, a medium-pressure mercury lamp, a low-pressure mercury lamp, or UV-LED is preferable.

In the step of obtaining an insulating layer, in order to obtain an insulating layer having a desired thickness, the step of applying the insulating ink and irradiating the insulating ink with an active energy ray is preferably repeated two or more times.

The thickness of the insulating layer is preferably 5 μm to 5,000 μm, and more preferably m to 2,000 μm.

(Insulating Ink)

In the present disclosure, the insulating ink means an ink for forming an insulating layer having insulating properties. The insulating properties mean properties of having a volume resistivity of 10¹⁰ Ωcm or more.

It is preferable that the insulating ink contain a polymerizable monomer and a polymerization initiator.

—Polymerizable Monomer—

The polymerizable monomer means a monomer having at least one polymerizable group in one molecule. The polymerizable group in the polymerizable monomer may be a cationically polymerizable group or a radically polymerizable group. From the viewpoint of curing properties, the polymerizable group is preferably a radically polymerizable group. Furthermore, from the viewpoint of curing properties, the radically polymerizable group is preferably an ethylenically unsaturated group.

In the present disclosure, a monomer means a compound having a molecular weight of 1,000 or less. The molecular weight can be calculated from the type and number of atoms constituting the compound.

The polymerizable monomer may be a monofunctional polymerizable monomer having one polymerizable group or a polyfunctional polymerizable monomer having two or more polymerizable groups.

The monofunctional polymerizable monomer is not particularly limited as long as it is a monomer having one polymerizable group. From the viewpoint of curing properties, the monofunctional polymerizable monomer is preferably a monofunctional radically polymerizable monomer, and more preferably a monofunctional ethylenically unsaturated monomer.

Examples of the monofunctional ethylenically unsaturated monomer include monofunctional (meth)acrylate, monofunctional (meth)acrylamide, a monofunctional aromatic vinyl compound, monofunctional vinyl ether, and a monofunctional N-vinyl compound.

Examples of the monofunctional (meth)acrylate include methyl (meth)acrylate, ethyl (meth)acrylate, propyl (meth)acrylate, n-butyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, lauryl (meth)acrylate, stearyl (meth)acrylate, isostearyl (meth)acrylate, cyclohexyl (meth)acrylate, 4-n-butylcyclohexyl (meth)acrylate, 4-tert-butylcyclohexyl (meth)acrylate, bornyl (meth)acrylate, isobornyl (meth)acrylate, 2-ethylhexyldiglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, 3-methoxybutyl (meth)acrylate, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, 2-phenoxymethyl (meth)acrylate, 2-phenoxyethyl (meth)acrylate, glycidyl (meth)acrylate, glycidyloxybutyl (meth)acrylate, glycidyloxyethyl (meth)acrylate, glycidyloxypropyl (meth)acrylate, tetrahydrofurfuryl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 3-hydroxybutyl (meth)acrylate, 4-hydroxybutyl (meth)acrylate, cyclic trimethylolpropane formal(meth)acrylate, phenylglycidyl ether (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethylsilylpropyl (meth)acrylate, polyethylene oxide monomethyl ether (meth)acrylate, polyethylene oxide (meth)acrylate, polyethylene oxide monoalkyl ether (meth)acrylate, dipropylene glycol (meth)acrylate, polypropylene oxide monoalkyl ether (meth)acrylate, 2-methacryloyloxyethyl succinate, 2-methacryloyloxyhexahydrophthalic acid, 2-methacryloyloxyethyl-2-hydroxypropyl phthalate, ethoxydiethylene glycol (meth)acrylate, butoxydiethylene glycol (meth)acrylate, trifluoroethyl (meth)acrylate, perfluorooctylethyl (meth)acrylate, 2-hydroxy-3-phenoxypropyl (meth)acrylate, ethylene oxide (EO)-modified phenol (meth)acrylate, EO-modified cresol (meth)acrylate, EO-modified nonylphenol (meth)acrylate, propylene oxide (PO)-modified nonylphenol (meth)acrylate, EO-modified-2-ethylhexyl (meth)acrylate, dicyclopentenyl (meth)acrylate, dicyclopentenyloxyethyl (meth)acrylate, dicyclopentanyl (meth)acrylate, (3-ethyl-3-oxetanylmethyl) (meth)acrylate, phenoxyethylene glycol (meth)acrylate, 2-carboxyethyl (meth)acrylate, and 2-(meth)acryloyloxyethyl succinate.

Examples of the monofunctional (meth)acrylamide include (meth)acrylamide, N-methyl (meth)acrylamide, N-ethyl (meth)acrylamide, N-propyl (meth)acrylamide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound include styrene, dimethylstyrene, trimethylstyrene, isopropylstyrene, chloromethylstyrene, methoxystyrene, acetoxystyrene, chlorostyrene, dichlorostyrene, bromostyrene, vinyl benzoic acid methyl ester, 3-methylstyrene, 4-methylstyrene, 3-ethylstyrene, 4-ethylstyrene, 3-propylstyrene, 4-propylstyrene, 3-butylstyrene, 4-butylstyrene, 3-hexylstyrene, 4-hexylstyrene, 3-octylstyrene, 4-octylstyrene, 3-(2-ethylhexyl)styrene, 4-(2-ethylhexyl)styrene, allyl styrene, isopropenyl styrene, butenyl styrene, octenyl styrene, 4-t-butoxycarbonyl styrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexyl methyl vinyl ether, 4-methylcyclohexyl methyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional N-vinyl compound include N-vinyl-F-caprolactam and N-vinylpyrrolidone.

The polyfunctional polymerizable monomer is not particularly limited as long as it is a monomer having two or more polymerizable groups. From the viewpoint of curing properties, the polyfunctional polymerizable monomer is preferably a polyfunctional radically polymerizable monomer, and more preferably a polyfunctional ethylenically unsaturated monomer.

Examples of the polyfunctional ethylenically unsaturated monomer include a polyfunctional (meth)acrylate compound and a polyfunctional vinyl ether.

Examples of the polyfunctional (meth)acrylate include ethylene glycol di(meth)acrylate, diethylene glycol di(meth)acrylate, triethylene glycol di(meth)acrylate, polyethylene glycol di(meth)acrylate, propylene glycol di(meth)acrylate, dipropylene glycol di(meth)acrylate, tripropylene glycol di(meth)acrylate, polypropylene glycol di(meth)acrylate, butylene glycol di(meth)acrylate, tetraethylene glycol di(meth)acrylate, neopentyl glycol di(meth)acrylate, 3-methyl-1,5-pentanediol di(meth)acrylate, 1,6-hexanediol di(meth)acrylate, heptanediol di(meth)acrylate, EO-modified neopentyl glycol di(meth)acrylate, PO-modified neopentyl glycol di(meth)acrylate, EO-modified hexanediol di(meth)acrylate, PO-modified hexanediol di(meth)acrylate, octanediol di(meth)acrylate, nonanediol di(meth)acrylate, decanediol di(meth)acrylate, dodecanediol di(meth)acrylate, glycerin di(meth)acrylate, pentaerythritol di(meth)acrylate, ethylene glycol diglycidyl ether di(meth)acrylate, diethylene glycol diglycidyl ether di(meth)acrylate, tricyclodecanedimethanol di(meth)acrylate, trimethylolethane tri(meth)acrylate, trimethylolpropane tri(meth)acrylate, trimethylolpropane EO-added tri(meth)acrylate, pentaerythritol tri(meth)acrylate, pentaerythritol tetra(meth)acrylate, dipentaerythritol tetra(meth)acrylate, dipentaerythritol penta(meth)acrylate, dipentaerythritol hexa(meth)acrylate, tri(meth)acryloyloxyethoxytrimethylolpropane, glycerin polyglycidyl ether poly(meth)acrylate, and tris(2-acryloyloxyethyl) isocyanurate.

Examples of the polyfunctional vinyl ether include 1,4-butanediol divinyl ether, ethylene glycol divinyl ether, diethylene glycol divinyl ether, triethylene glycol divinyl ether, polyethylene glycol divinyl ether, propylene glycol divinyl ether, butylene glycol divinyl ether, hexanediol divinyl ether, 1,4-cyclohexanedimethanol divinyl ether, bisphenol A alkylene oxide divinyl ether, bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, EO-added trimethylolpropane trivinyl ether, PO-added trimethylolpropane trivinyl ether, EO-added ditrimethylolpropane tetravinyl ether, PO-added ditrimethylolpropane tetravinyl ether, EO-added pentaerythritol tetravinyl ether, PO-added pentaerythritol tetravinyl ether, EO-added dipentaerythritol hexavinyl ether, and PO-added dipentaerythritol hexavinyl ether.

The content of the polymerizable monomer with respect to the total amount of the insulating ink is preferably 10% by mass to 98% by mass, and more preferably 50% by mass to 98% by mass.

—Polymerization Initiator—

Examples of the polymerization initiator contained in the insulating ink include an oxime compound, an alkylphenone compound, an acylphosphine compound, an aromatic onium salt compound, an organic peroxide, a thio compound, a hexaarylbisimidazole compound, a borate compound, an azinium compound, a titanocene compound, an active ester compound, a carbon halogen bond-containing compound, and an alkylamine.

Particularly, from the viewpoint of further improving conductivity, the polymerization initiator contained in the insulating ink is preferably at least one compound selected from the group consisting of an oxime compound, an alkylphenone compound, and a titanocene compound, more preferably an alkylphenone compound, and even more preferably at least one compound selected from the group consisting of an α-aminoalkylphenone compound and a benzyl ketal alkylphenone.

The content of the polymerization initiator with respect to the total amount of the insulating ink is preferably 0.5% by mass to 20% by mass, and more preferably 2% by mass to 10% by mass.

In the present disclosure, the insulating ink may contain other components different from the polymerization initiator and the polymerizable monomer. Examples of the other components include a sensitizer, a surfactant, and additives.

(Sensitizer)

The insulating ink may contain at least one sensitizer.

Examples of the sensitizer include a polynuclear aromatic compound (for example, pyrene, perylene, triphenylene, and 2-ethyl-9,10-dimethoxyanthracene), a xanthene-based compound (for example, fluorescein, eosin, erythrosin, rhodamine B, and rose bengal), a cyanine-based compound (for example, thiacarbocyanine and oxacarbocyanine), a merocyanine-based compound (for example, merocyanine and carbomerocyanine), a thiazine-based compound (for example, thionine, methylene blue, and toluidine blue), an acridine-based compound (for example, acridine orange, chloroflavine, and acryflavine), anthraquinones (for example, anthraquinone), a squarylium-based compound (for example, squarylium), a coumarin-based compound (for example, 7-diethylamino-4-methylcoumarin), a thioxanthone-based compound (for example, isopropylthioxanthone), and a thiochromanone-based compound (for example, thiochromanone). Among these, as the sensitizer, a thioxanthone-based compound is preferable.

In a case where the insulating ink contains a sensitizer, the content of the sensitizer is not particularly limited, but is preferably 1.0% by mass to 15.0% by mass and more preferably 1.5% by mass to 5.0% by mass with respect to the total amount of the insulating ink.

(Chain Transfer Agent)

An ink for forming an insulating protective layer may contain at least one chain transfer agent.

From the viewpoint of improving the reactivity of a photopolymerization reaction, the chain transfer agent is preferably a polyfunctional thiol.

Examples of the polyfunctional thiol include aliphatic thiols such as hexane-1,6-dithiol, decane-1,10-dithiol, dimercaptodiethyl ether, and dimercaptodiethyl sulfide, aromatic thiols such as xylylene dimercaptan, 4,4′-dimercaptodiphenylsulfide, and 1,4-benzenedithiol; poly(mercaptoacetate) of a polyhydric alcohol such as ethylene glycol bis(mercaptoacetate), polyethylene glycol bis(mercaptoacetate), propylene glycol bis(mercaptoacetate), glycerin tris(mercaptoacetate), trimethylolethane tris(mercaptoacetate), trimethylolpropane tris(mercaptoacetate), pentaerythritol tetrakis(mercaptoacetate), and dipentaerythritol hexakis(mercaptoacetate); poly(3-mercaptopropionate) of a polyhydric alcohol such as ethylene glycol bis(3-mercaptopropionate), polyethylene glycol bis(3-mercaptopropionate), propylene glycol bis(3-mercaptopropionate), glycerin tris(3-mercaptopropionate), trimethylolethane tris(mercaptopropionate), trimethylolpropane tris(3-mercaptopropionate), pentaerythritol tetrakis(3-mercaptopropionate), and dipentaerythritol hexakis(3-mercaptopropionate); poly(mercaptobutyrate) such as 1,4-bis(3-mercaptobutyryloxy)butane, 1,3,5-tris(3-mercaptobutyloxyethyl)-1,3,5-triazine-2,4,6(1H,3H,5H)-trione, and pentaerythritol tetrakis(3-mercaptobutyrate).

(Surfactant)

The insulating ink may contain at least one surfactant.

Examples of the surfactant include the surfactants described in JP1987-173463A (JP-S62-173463A) and JP1987-183457A (JP-S62-183457A). Examples of the surfactant include anionic surfactants such as dialkyl sulfosuccinate, alkyl naphthalene sulfonate, and a fatty acid salt, nonionic surfactants such as polyoxyethylene alkyl ether, polyoxyethylene alkyl allyl ether, acetylene glycol, and a polyoxyethylene-polyoxypropylene block copolymer, and cationic surfactants such as an alkylamine salt and a quaternary ammonium salt. The surfactant may also be a fluorine-based surfactant or a silicone-based surfactant.

In a case where the insulating ink contains a surfactant, the content of the surfactant with respect to the total amount of the insulating ink is preferably 1% by mass or less, and more preferably 0.5% by mass or less. The lower limit of the content of the surfactant is not particularly limited.

(Organic Solvent)

The insulating ink may contain at least one organic solvent.

Examples of the organic solvent include (poly)alkylene glycol monoalkyl ethers such as ethylene glycol monoethyl ether, diethylene glycol monoethyl ether, triethylene glycol monomethyl ether, propylene glycol monomethyl ether (PGME), dipropylene glycol monomethyl ether, and tripropylene glycol monomethyl ether;

(poly)alkylene glycol dialkyl ethers such as ethylene glycol dibutyl ether, diethylene glycol dimethyl ether, diethylene glycol diethyl ether, dipropylene glycol diethyl ether, and tetraethylene glycol dimethyl ether;

(poly)alkylene glycol acetates such as diethylene glycol acetate;

(poly)alkylene glycol diacetates such as ethylene glycol diacetate and propylene glycol diacetate;

(poly)alkylene glycol monoalkyl ether acetates such as ethylene glycol monobutyl ether acetate and propylene glycol monomethyl ether acetate, ketones such as methyl ethyl ketone and cyclohexanone;

lactones such as γ-butyrolactone;

esters such as ethyl acetate, propyl acetate, butyl acetate, 3-methoxybutyl acetate (MBA), methyl propionate, and ethyl propionate;

cyclic ethers such as tetrahydrofuran and dioxane; and

amides such as dimethylformamide and dimethylacetamide.

In a case where the insulating ink contains an organic solvent, the content of the organic solvent with respect to the total amount of the insulating ink is preferably 70% by mass or less, and more preferably 50% by mass or less. The lower limit of the content of the organic solvent is not particularly limited.

(Additive)

As necessary, the insulating ink may contain additives such as a co-sensitizer, an ultraviolet absorber, an antioxidant, an antifading agent, and a basic compound.

(Physical Properties)

From the viewpoint of improving jetting stability in a case where the insulating ink is applied using an ink jet recording method, the pH of the insulating ink is preferably 7 to 10, and more preferably 7.5 to 9.5. The pH is measured at 25° C. by using a pH meter, for example, a pH meter (model number “HM-31”) manufactured by DKK-TOA CORPORATION.

The viscosity of the insulating ink is preferably 0.5 mPa·s to 60 mPa·s, and more preferably 2 mPa·s to 40 mPa·s. The viscosity is measured at 25° C. by using a viscometer, for example, a TV-22 viscometer manufactured by TOKISANGYO.

The surface tension of the insulating ink is preferably 60 mN/m or less, more preferably 20 mN/m to 50 mN/m, and even more preferably 25 mN/m to 45 mN/m. The surface tension is measured at 25° C. by using a surface tensiometer, for example, an automatic surface tensiometer (trade name “CBVP-Z”) manufactured by Kyowa Interface Science Co., Ltd., by a plate method.

### EXAMPLES

Hereinafter, the present disclosure will be more specifically described based on examples, but the present disclosure is not limited to the following examples as long as the gist of the present disclosure is maintained.

<Preparation of Insulating Ink 1>

The following components were mixed together, and the mixture was stirred for 20 minutes at 25° C. under the conditions of 5,000 rpm by using a mixer (trade name “L4R”, manufactured by Silverson), thereby obtaining an insulating ink 1.
Omni. 379: 2-(dimethylamino)-2-(4-methylbenzyl)-1-(4-morpholinophenyl)-butan-1-one (trade name “Omnirad 379”, manufactured by IGM Resins B.V., Inc.) . . . 4.0% by mass
ITX: 2-isopropylthioxanthone (trade name “SPEEDCURE ITX”, manufactured by Lambson Ltd.) . . . 2.0% by mass
PEA: phenoxyethyl acrylate (manufactured by FUJIFILM Wako Pure Chemical Corporation) . . . 49.0% by mass
NVC: N-vinylcaprolactam (manufactured by FUJIFILM Wako Pure Chemical Corporation) . . . 22.0% by mass
TMPTA: trimethylolpropane triacrylate (manufactured by FUJIFILM Wako Pure Chemical Corporation) . . . 23.0% by mass

<Preparation of Conductive Ink 1>

1-Propanol (25.1 g), 20 g of silver acetate, and 5 g of formic acid were added to a 300 mL three-neck flask, and the mixture was stirred for 20 minutes. The generated silver salt precipitate was decanted 3 times by using 1-propanol and washed. 1-Propylamine (14.4 g) and 25.1 g of 1-propanol were added to the precipitate, and the mixture was stirred for 30 minutes. Then, 10 g of water was added thereto, and the mixture was further stirred, thereby obtaining a solution containing a silver complex. This solution was filtered using a membrane filter made of polytetrafluoroethylene (PTFE) having a pore diameter of 0.45 m, thereby obtaining a conductive ink 1.

<Preparation of Conductive Ink 2>

Water (46 g), 20.0 g of silver acetate, 20 g of ethylenediamine, and 20 g of amylamine were added to a 300 mL three-neck flask, and the mixture was stirred for 20 minutes. Formic acid (4 g) was added to the obtained solution, and the mixture was further stirred for 30 minutes, thereby obtaining a solution containing a silver complex. This solution was filtered using a membrane filter made of polytetrafluoroethylene (PTFE) having a pore diameter of 0.45 m, thereby obtaining a conductive ink 2.

<Preparation of Conductive Ink 3>

A conductive ink 3 was obtained by the same method as the conductive ink 1, except that the type and amount of complexing agent and the type and amount of solvent in the conductive ink 1 were changed as described in Table 1.

<Preparation of Conductive Ink 4>

Dehydrated oxalic acid (30 g) was dissolved in 350 mL of water, thereby preparing an aqueous oxalic acid solution. Furthermore, 30 g of silver nitrate was dissolved in 120 mL of water, thereby preparing an aqueous silver nitrate solution. The aqueous silver nitrate solution was added dropwise to the aqueous oxalic acid solution with stirring. After the end of the reaction, silver oxalate as a precipitate was isolated. The isolated silver oxalate (18 g) and 36.50 g of ethanol were added to a 200 mL three-neck flask. In an ice bath, 36 g of isopropanolamine was added dropwise to the obtained suspension for 10 minutes. Octylamine (12.5 g) was added thereto, and the mixture was stirred at room temperature (23° C.) for 2 hours, thereby obtaining a solution containing a silver complex. Polyvinylpyrrolidone (1.2 g) was added to 98.8 g of the aforementioned complex solution. This solution was filtered using a membrane filter made of polytetrafluoroethylene (PTFE) having a pore diameter of 0.45 m, thereby obtaining a conductive ink 4.

<Preparation of Conductive Inks 5 to 7>

Conductive inks 5 to 7 were obtained by the same method as the conductive ink 4, except that in the conductive ink 4, the type and content of metal salt not yet forming a complex, the type and content of solvent, and the type of reducing agent are changed as described in Table 1.

<Preparation of Conductive Ink 8>

Silver neodecanoate (40 g) was added to a 200 mL three-neck flask. Then, 30.0 g of trimethylbenzene and 30.0 g of terpineol were added thereto and stirred, thereby obtaining a solution containing a silver salt. This solution was filtered using a membrane filter made of polytetrafluoroethylene (PTFE) having a pore diameter of 0.45 m, thereby obtaining a conductive ink 8.

<Preparation of Conductive Ink 9>

Silver neodecanoate (25.0 g), 35 g of xylene, and 30.0 g of terpineol were added to a 200 mL three-neck flask, and dissolved. Then, 10 g of tert-octylamine was added thereto and stirred, thereby obtaining a solution containing a silver complex. The reaction was carried out at normal temperature (23° C.) for 2 hours, thereby obtaining a homogeneous solution. This solution was filtered using a membrane filter made of polytetrafluoroethylene (PTFE) having a pore diameter of 0.45 m, thereby obtaining a conductive ink 9.

<Preparation of Conductive Ink 10>

A conductive ink 10 was obtained by the same method as the conductive ink 9, except that tert-octylamine in the conductive ink 9 was changed to amylamine.

<Preparation of Conductive Ink 11>

A conductive ink 11 was obtained by the same method as the conductive ink 9, except that 1 g of tert-octylamine in the conductive ink 9 was changed to 0.5 g of amylamine and 0.5 g of octylamine.

<Preparation of Conductive Ink 12>

Isobutylammonium carbonate (26.14 g) and 64.0 g of isopropyl alcohol were added to a 200 mL three-neck flask, and dissolved. Then, 9.0 g of silver oxide was added thereto and reacted at normal temperature (23° C.) for 2 hours, thereby obtaining a homogeneous solution. Furthermore, 1.29 g of 2-hydroxy-2-methylpropylamine was added thereto and stirred, thereby obtaining a solution containing a silver complex. This solution was filtered using a membrane filter made of polytetrafluoroethylene (PTFE) having a pore diameter of 0.45 m, thereby obtaining a conductive ink 12.

<Preparation of Conductive Ink 13>

A conductive ink 13 was obtained by the same method as the conductive ink 3, except that the amount of complexing agent and the amount of reducing agent in the conductive ink 3 were changed as described in Table 1.

<Preparation of Conductive Ink 14>

As a dispersant, 6.8 g of polyvinylpyrrolidone (weight-average molecular weight 3,000, manufactured by Sigma-Aldrich Corporation) was dissolved in 100 mL of water, thereby preparing a solution a. In addition, 50.00 g of silver nitrate was dissolved in 200 mL of water, thereby preparing a solution b. The solution a and the solution b were mixed together and stirred, thereby obtaining a mixed solution. At room temperature (23° C.), 78.71 g of an 85% by mass aqueous N,N-diethylhydroxylamine solution was added dropwise to the mixed solution. In addition, a solution obtained by dissolving 6.8 g of polyvinylpyrrolidone in 1,000 mL of water was slowly added dropwise to the mixed solution at room temperature. The obtained suspension was passed through an ultrafiltration unit (Vivaflow 50 manufactured by Sartorius Stedim Biotech GmbH, molecular weight cut-off: 100,000, number of units: 4) and purified by being passed through purified water until about 5 L of exudate is discharged from the ultrafiltration unit. The supply of purified water was stopped, followed by concentration, thereby obtaining 30 g of a silver particle dispersion liquid 1. The content of solids in this dispersion is 50% by mass. The content of silver in the solids that was measured by TG-DTA (simultaneous measurement of thermogravimetry and differential thermal analysis) (manufactured by Hitachi High-Tech Corporation, model: STA7000 series) was 96.0% by mass. The obtained silver particle dispersion liquid 1 was 20× diluted with deionized water, and measured using a particle size analyzer FPAR-1000 (manufactured by Otsuka Electronics Co., Ltd) to determine the volume-average particle diameter of the silver particles. The volume-average particle diameter of the silver particle dispersion liquid 1 was 60 nm.

2-Propanol (2 g) and 0.1 g of OLFINE E-1010 (manufactured by Nissin Chemical Industry Co., Ltd.) as a surfactant were added to 10 g of the silver particle dispersion liquid, and water was added thereto such that the silver concentration reaches 40% by mass, thereby obtaining a conductive ink 14.

Table 1 shows the types and contents (% by mass) of the components contained in the conductive inks 1 to 14. First, whether the metal compound contained in each conductive ink is a metal complex, a metal salt, or metal particles is described table. Furthermore, in a case where the metal compound is a metal complex, the type of metal salt not yet forming a complex and the type of complexing agent are also described in the table.

Details of the abbreviations in Table 1 are as follows.

—Complexing Agent—
PA: 1-propylamine
EDA: ethylenediamine
EA: ethylamine
iPrOHA: isopropanolamine
AA: amylamine
EtOHA: ethanolamine
OA: octylamine
2HMPA: 2-hydroxy-2-methylpropylamine
tOA: t-octylamine
IBAC: Isobutylammonium carbonate

—Solvent—
1PrOH: 1-propanol
H₂O: water
MeOH: methanol
EtOH: ethanol
IPA: isopropanol
TO: terpineol
TMB: trimethylbenzene
XL: xylene

—Reducing Agent—
FA: formic acid

—Resin—
PVP: polyvinylpyrrolidone

TABLE 1

| | | Metal salt | | Complexing agent 1 | | Complexing agent 2 | |
|---|---|---|---|---|---|---|---|
| | | | Content | | Content | | Coment |
| | Form | Type | (% by mass) | Type | (% by mass) | Type | (% by mass) |
| Conductive | Metal | Silver acetate | 20 | PA | 14.4 | — | — |
| ink 1 | Complex | | | | | | |
| Conductive | Metal | Silver acetate | 20 | EDA | 20 | AA | 10.0 |
| ink 2 | complex | | | | | | |
| Conductive | Metal | Silver acetate | 20 | EA | 3.6 | EtOHA | 15.0 |
| ink 3 | complex | | | | | | |
| Conductive | Metal | Silver oxalate | 18 | iPrOHA | 36 | OA | 9.0 |
| ink 4 | complex | | | | | | |
| Conductive | Metal | Silver acetate | 20 | iPrOHA | 36 | OA | 9.0 |
| ink 5 | complex | | | | | | |
| Conductive | Metal | Silver acetate | 20 | iPrOHA | 36 | OA | 9.0 |
| ink 6 | complex | | | | | | |
| Conductive | Metal | Silver acetate | 20 | iPrOHA | 36 | OA | 9.0 |
| ink 7 | complex | | | | | | |
| Conductive | Metal salt | Silver | 40 | — | — | — | — |
| ink 8 | | neodecanoate | | | | | |
| Conductive | Metal | Silver | 25 | tOA | 10 | — | — |
| ink 9 | Complex | neodecanoate | | | | | |
| Conductive | Metal | Silver | 25 | AA | 10 | — | — |
| ink 10 | complex | neodecanoate | | | | | |
| Conductive | Metal | Silver | 25 | AA | 5 | OA | 5.0 |
| ink 11 | complex | neodecanoate | | | | | |
| Conductive | Metal | Silver oxide | 8.6 | IBAC | 26.11 | 2HMPA | 1.29 |
| ink 12 | complex | | | | | | |
| Conductive | Metal | Silver acetate | 20 | EA | 3.6 | BOHA | 6.0 |
| ink 13 | complex | | | | | | |

| | | |
|---|---|---|
| Conductive | Metal | — |
| ink 14 | particles | |

| | Solvent 1 | | Solvent 2 | | Reducing agent | | Resin | |
|---|---|---|---|---|---|---|---|---|
| | | Content | | Content | | Content | | Content |
| | Type | (% by mass ) | Type | (% by mass) | Type | (% by mass) | Type | (% by mass) |
| Conductive | IPrOH | 50.2 | H₂O | 10.0 | FA | 5.0 | — | — |
| ink 1 | | | | | | | | |
| Conductive | H₂O | 46.0 | — | — | FA | 4.0 | — | — |
| ink 2 | | | | | | | | |
| Conductive | MeOH | 40.4 | H₂O | 19.0 | FA | 2.0 | — | — |
| ink 3 | | | | | | | | |
| Conductive | EtOH | 35.9 | — | — | — | — | PVP | 1.2 |
| ink 4 | | | | | | | | |
| Conductive | EtOH | 33.8 | — | — | — | — | PVP | 1.2 |
| ink 5 | | | | | | | | |
| Conductive | EtOH | 34.5 | — | — | FA | 0.5 | — | — |
| ink 6 | | | | | | | | |
| Conductive | H₂O | 34.5 | — | — | FA | 0.5 | — | — |
| ink 7 | | | | | | | | |
| Conductive | TMB | 30.0 | TO | 30.0 | — | — | — | — |
| ink 8 | | | | | | | | |
| Conductive | XL | 35.0 | TO | 30.0 | — | — | — | — |
| ink 9 | | | | | | | | |
| Conductive | XL | 35.0 | TO | 30.0 | — | — | — | — |
| ink 10 | | | | | | | | |
| Conductive | XL | 35.0 | TO | 30.0 | — | — | — | — |
| ink 11 | | | | | | | | |
| Conductive | IPA | 64.0 | — | — | — | — | — | — |
| ink 12 | | | | | | | | |
| Conductive | MeOH | 40.4 | H₂O | 29.0 | FA | 1.0 | — | — |
| ink 13 | | | | | | | | |

| | |
|---|---|
| Conductive | — |
| ink 14 | |

### Example 1

—Preparation of Laminate Sample 1—

As a base material, a polyimide film (trade name “KAPTON”, manufactured by DU PONT-TORAY CO., LTD.) was prepared. An ink jet head (trade name “SG1024”, manufactured by FUJIFILM Dimatix, Inc.) was filled with the insulating ink 1. As image recording conditions, the resolution was set to 1,200 dots per inch (dpi), and the liquid droplet volume was set to 10 pL per dot. An ultraviolet lamp-type irradiator (365 nm LED, peak intensity 8 W/cm², irradiation area 2×8 cm, prepared by FUJIFILM Corporation) was prepared next to the ink jet head. An operation of performing exposure while recording an image on the base material was repeated, thereby recording a solid image having a width of 10 cm, a length of 5 cm, and a thickness of 100 m. In this way, an insulating layer was formed on the base material.

The base material on which the insulating layer was formed was preheated to 45° C. The conductive ink was jetted onto the insulating layer, and 5.0 seconds after a time when the conductive ink has been landed, ultraviolet irradiation was performed at an illuminance of 4 W/cm² for 10 seconds, thereby recording an image having a width of 5 cm and a length of 2.0 cm. An operation of jetting the conductive ink and performing ultraviolet irradiation 5.0 seconds after a time when the conductive ink was landed was repeated, thereby recording an image. This operation was performed eight times in total in the same region (lamination step), thereby obtaining a laminate sample 1 in which a conductive layer with metallic gloss having a thickness of 3.2 m was formed. The total exposure amount of the ultraviolet was 40 J/cm².

—Preparation of Laminate Sample 2—

A solid image having a width of 2.5 cm, a length of 2.5 cm, and a thickness of 100 m was recorded on a base material by using the insulating ink 1 by the same method as the method of preparing the laminate sample 1. In this way, an insulating layer was formed on the base material.

A laminate sample 2 in which a conductive layer with metallic gloss having a thickness of 3.2 m was formed was obtained by the same method as the method of preparing the laminate sample 1, except that instead of the image having a width of 5 cm and a length of 2.5 cm, an image composed of four lines each having a length of 5 cm was recorded as a line-and-space pattern image. In the line-and-space pattern image, L/S was set to 100 μm/75 μm, 100 μm/100 μm, 100 μm/125 μm, and 100 μm/150 μm. L means a line width and S means a space width.

—Preparation of Laminate Sample 3—

A laminate sample 3 was prepared by the same method as the method of preparing the laminate sample 1, except that a polyimide film (trade name “KAPTON”, manufactured by DU PONT-TORAY CO., LTD.) preliminarily coated with a solder resist (trade name “PSR-4000 AM02”, manufactured by TAIYO INK MFG CO., LTD.) was used as a base material.

—Preparation of Laminate Sample 4—

A laminate sample 4 was prepared by the same method as the method of preparing the laminate sample 2, except that a polyimide film (trade name “KAPTON”, manufactured by DU PONT-TORAY CO., LTD.) preliminarily coated with a solder resist (trade name “PSR-4000 AM02”, manufactured by TAIYO INK MFG CO., LTD.) was used as a base material.

—Preparation of Laminate Sample 5—

As a base material, a print substrate was prepared on which a rectangular electronic component (manufactured by Spansion LLC) insulated with a 10 mm×12 mm×1 mm (thickness) epoxy molding compound (EMC) was mounted. The base material was preheated to 45° C., and the conductive ink 1 was jetted from an ink jet head (trade name “SG1024”, manufactured by FUJIFILM Dimatix, Inc.) at a resolution of 1,200 dots per inch (dpi) and a liquid droplet volume of 10 pL per dot. Five point zero seconds after a time when the conductive ink was landed, ultraviolet irradiation was performed at an illuminance of 4 W/cm² for 10 seconds, such that an image having a width of 1.2 cm and a length of 1.4 cm covering the electronic component was recorded. An operation of jetting the conductive ink and performing ultraviolet irradiation 5.0 seconds after a time when the conductive ink was landed was repeated, thereby recording an image. This operation was performed eight times in total in the same region (lamination step), thereby obtaining a laminate sample 1 in which a conductive layer with metallic gloss having a thickness of 3.2 m was formed. The total exposure amount of the ultraviolet was 40 J/cm².

### Examples 2 to 7 and Examples 9 to 13

In Examples 2 to 7, 12, and 13, the laminate samples 1 to 4 were prepared by the same method as in Example 1, except that the type of conductive ink was changed as described in Table 2.

In Examples 9 to 11, the laminate samples 1 to 4 were prepared by the same method as in Example 1, except that the type of conductive ink was changed as described in Table 2, and the base material on which the insulating layer was formed was preheated to 60° C.

### Examples 8 and 14

In Example 8, the conductive ink 1 used in Example 1 was changed to a conductive ink 8. Furthermore, the base material on which the insulating layer was formed was preheated to 60° C. In addition, the laminate samples 1 to 4 were prepared by the same method as in Example 1, except that an operation was performed eight times in total, the operation including jetting the conductive ink, performing ultraviolet irradiation 5.0 seconds after a time when the conductive ink was landed, and performing heating at 160° C. for 20 minutes by using an oven 10 seconds after a time when the ultraviolet irradiation ended.

In Example 14, the conductive ink 1 used in Example 1 was changed to a conductive ink 14. In addition, the laminate samples 1 to 4 were prepared by the same method as in Example 1, except that an operation was performed eight times in total, the operation including jetting the conductive ink, performing ultraviolet irradiation 5.0 seconds after a time when the conductive ink was landed, and performing heating at 160° C. for 20 minutes by using an oven 10 seconds after a time when the ultraviolet irradiation ended.

### Examples 15 to 33 and Comparative Examples 2 and 3

In Examples 15 to 33, the laminate samples 1 to 4 were prepared by the same method as in Example 1, except that the number of times the conductive ink is applied, the number of times of exposure, the type of light source, the total exposure amount, the time from a time when the conductive ink was landed to a time when the ultraviolet irradiation begins (described as “How long it takes to start exposure” in the table), and the temperature of the base material at the time of jetting the conductive ink (described as “Temperature of base material” in the table) were changed as described in Table 2. For Examples 20 to 24, a laminate sample 5 was also prepared. In Example 15, a metal halide lamp (trade name “F300S-6 SYSTEM (H-valve)”, manufactured by Heraeus Holding, “MH” in the table) was used.

### Example 34

In Example 34, the liquid droplet volume of the conductive ink was set to 20 pL, and the resolution in the scan direction was set to 2,400 dpi. In addition, the laminate samples 1 to 4 were prepared by the same method as in Example 1, except that an operation was performed twice in total, the operation including jetting the conductive ink and performing ultraviolet irradiation 5.0 seconds after a time when the conductive ink was landed.

### Example 35

In Example 35, the conductive ink was continuously jetted four times onto the insulating layer, and ultraviolet irradiation was performed 5.0 seconds after a time when the fourth conductive ink was landed. In addition, the laminate samples 1 to 4 were prepared by the same method as in Example 1, except that the conductive ink was continuously jetted four times, and ultraviolet irradiation was performed 5.0 seconds after a time when the fourth conductive ink (the eighth conductive ink among all conductive inks) was landed.

### Example 36

In Example 36, the laminate samples 1 to 4 were prepared by the same method as in Example 1, except that the conductive ink was jetted onto the insulating layer, the conductive ink was continuously jetted eight times, and ultraviolet irradiation was performed 5.0 seconds after a time when the eight conductive ink was landed.

### Comparative Example 1

In Comparative Example 1, the laminate samples 1 to 4 were prepared by the same method as in Example 4, except that a pulse generator (trade name “SINTERON 2000”, manufactured by XENON Corporation) was used, and ultraviolet irradiation was performed 1,800 seconds after a time when the conductive ink was landed.

By using the laminate samples 1 to 5 obtained in each of examples and comparative examples, image quality, conductivity, and adhesiveness were evaluated. The measuring method and the evaluation method are as follows. The measurement results and the evaluation results are shown in Table 2.

<Image Quality>

The conductive layer in each of the laminate samples 2 and 4 was observed with a 5× objective lens of a microscope (trade name: “laser microscope VK-X1000”, manufactured by KEYENCE CORPORATION). The image quality was evaluated by checking whether or not the space between the lines was maintained in the line-and-space pattern image. The evaluation standard is as follows. Table 2 shows the evaluation results.

5: All the spaces having widths of 75 m, 100 m, 125 m, and 150 m are maintained.

4: Although the space having a width of 75 m is not maintained, spaces having other widths are maintained.

3: Although the spaces having widths of 75 m and 100 m are not maintained, spaces having other widths are maintained.

2: Although the spaces having widths of 75 m, 100 m, and 125 m are not maintained, the space having a width of 150 m is maintained.

1: None of the spaces having widths of 75 m, 100 m, 125 m, and 150 m are maintained.

<Conductivity>

For the conductive layer of each of the laminate samples 1 and 3, by using a resistivity meter (trade name “Loresta GP”, manufactured by Mitsubishi Chemical Analytech Co., Ltd.), the surface resistivity [Q/square] was measured at room temperature (23° C.) by a 4-terminal method. The evaluation standard is as follows. The conductive layer ranked 2 or higher is at a level having no problem for practical use.

5: The surface resistivity is less than 100 mΩ/square.

4: The surface resistivity is 100 mΩ/square or more and less than 250 mΩ/square.

3: The surface resistivity is 250 mΩ/square or more and less than 500 mΩ/square.

2: The surface resistivity is 500 mΩ/square or more and less than 1 Ω/square.

1: The surface resistivity is 1 Ω/square or more.

<Adhesiveness>

The laminate samples 1 and 3 were prepared and then left to stand at 25° C. for 1 hour. After 1 hour, a piece of CELLOTAPE (registered trademark, No. 405, manufactured by NICHIBAN Co., Ltd., width 12 mm, also simply called “tape” hereinafter) was attached onto the conductive layer of each of the laminate samples 1 and 3. Then, the piece of tape was peeled off from the image to evaluate the adhesiveness between the insulating layer and the conductive layer.

Specifically, the tape was attached and peeled off by the following method.

The tape was unwound at a constant speed and cut in a length of about 75 mm, thereby obtaining a piece of tape.

The obtained piece of tape was stacked on the conductive layer of the laminate sample 1, and the central region of the piece of tape having a width of 12 mm and a length of 25 mm was attached with a finger and rubbed hard with a fingertip.

After the piece of tape was attached, the end of the piece of tape was grasped and peeled off for 0.5 seconds to 1.0 seconds at an angle as close to 600 as possible.

Whether or not the peeled piece of tape had an attachment and whether or not the conductive layer in the laminate sample 1 was peeled off were visually observed. The adhesiveness between the insulating layer and the conductive layer was evaluated according to the following evaluation standard. The evaluation standard is as follows. Table 2 shows the evaluation results.

5: The piece of tape is found to have no attachment, and peeling of the conductive layer is not observed.

4: Although the piece of tape is found to have few attachments, peeling of the conductive layer is not observed.

3: Although the piece of tape is found to have few attachments, and the conductive layer is found to be slightly peeled off, the attachments and the peeling are within an acceptable range for practical use.

2: The piece of tape is found to have attachment, and the conductive layer is found to be peeled off, which are out of an acceptable range for practical use.

1: The piece of tape is found to have attachment, most of the conductive layer is peeled off, and the insulating layer is visible.

<Coating Properties>

The coating condition of the upper and lateral surfaces of the coated electronic component in the laminate sample 5 was observed with an optical microscope. Based on the coating condition, coating properties were evaluated. The evaluation standard is as follows. The sample ranked 3 or higher is at a level having no problem for practical use. Table 3 shows the evaluation results.

3: All the surfaces are coated.

2: Although the upper surface is coated, the lateral surfaces have an uncoated portion.

1: All the surfaces have an uncoated portion.

Table 2 shows the type of conductive ink, the average thickness of each layer, the number of times the conductive ink is applied, the number of times of exposure, the type of light source, the temperature of the base material at the time of applying the conductive ink, how long it takes to start exposure, the total exposure amount, and the residual amount of the liquid component. The evaluation result of the image quality obtained using the laminate sample 2 was the same as the evaluation result of the image quality obtained using the laminate sample 4. In addition, the evaluation results of the conductivity and adhesiveness obtained using the laminate sample 1 were the same as the evaluation results of the conductivity and adhesiveness obtained using the laminate sample 3.

TABLE 2

| | | Average | | | | |
|---|---|---|---|---|---|---|
| | | thickness | Application | | | Temperature |
| | Type of | of each | of ink | Exposure | | of base |
| | conductive | layer | (number of | (number of | Light | material |
| | ink | (μm) | times) | times) | source | (° C.) |
| Example 1 | Conductive | 0.4 | 8 | 8 | 365 nm | 45 |
| | ink 1 | | | | LED | |
| Example 2 | Conductive | 0.4 | 8 | 8 | 365 nm | 45 |
| | ink 2 | | | | LED | |
| Example 3 | Conductive | 0.4 | 8 | 8 | 365 nm | 45 |
| | ink 3 | | | | LED | |
| Example 4 | Conductive | 0.4 | 8 | 8 | 365 nm | 45 |
| | ink 4 | | | | LED | |
| Example 5 | Conductive | 0.4 | 8 | 8 | 365 nm | 45 |
| | ink 5 | | | | LED | |
| Example 6 | Conductive | 0.4 | 8 | 8 | 365 am | 45 |
| | ink 6 | | | | LED | |
| Example 7 | Conductive | 0.4 | 8 | 8 | 365 mm | 45 |
| | ink 7 | | | | LED | |
| Example 8 | Conductive | 0.4 | 8 | 8 | 365 nm | 60 |
| | ink 8 | | | | LED | |
| Example 9 | Conductive | 0.4 | 8 | 8 | 365 nm | 60 |
| | ink 9 | | | | LED | |
| Example 10 | Conductive | 0.4 | 8 | 8 | 365 nm | 60 |
| | ink 10 | | | | LED | |
| Example 11 | Conductive | 0.4 | 8 | 8 | 365 am | 60 |
| | ink 11 | | | | LED | |
| Example 12 | Conductive | 0.4 | 8 | 8 | 365 nm | 45 |
| | ink 12 | | | | LED | |
| Example 13 | Conductive | 0.4 | 8 | 8 | 365 nm | 45 |
| | ink 13 | | | | LED | |
| Example 14 | Conductive | 10 | 8 | 8 | 365 nm | 45 |
| | ink 14 | | | | LED | |
| Example 15 | Conductive | 0.4 | 8 | 8 | MH | 45 |
| | ink 1 | | | | | |
| Example 16 | Conductive | 0.4 | 8 | 8 | 385 nm | 45 |
| | ink 1 | | | | LED | |
| Example 17 | Conductive | 0.4 | 8 | 8 | 405 nm | 45 |
| | ink 1 | | | | LED | |
| Example 18 | Conductive | 0.4 | 8 | 8 | 365 nm | 45 |
| | ink 1 | | | | LED | |
| Example 19 | Conductive | 0.4 | 8 | 8 | 365 nm | 45 |
| | ink 1 | | | | LED | |
| Example 20 | Conductive | 0.4 | 8 | 8 | 365 nm | 45 |
| | ink 1 | | | | LED | |
| Example 21 | Conductive | 0.4 | 8 | 8 | 365 nm | 45 |
| | ink 1 | | | | LED | |
| Example 22 | Conductive | 0.4 | 8 | 8 | 365 nm | 45 |
| | ink 1 | | | | LED | |
| Example 23 | Conductive | 0.4 | 8 | 8 | 365 nm | 45 |
| | ink 1 | | | | LED | |
| Example 24 | Conductive | 0.4 | 8 | 8 | 365 nm | 45 |
| | ink 1 | | | | LED | |
| Example 25 | Conductive | 0.4 | 8 | 8 | 365 nm | 45 |
| | ink 1 | | | | LED | |
| Example 26 | Conductive | 0.4 | 8 | 8 | 365 nm | 45 |
| | ink 1 | | | | LED | |
| Example 27 | Conductive | 0.4 | 8 | 8 | 365 nm | 60 |
| | ink 1 | | | | LED | |
| Example 28 | Conductive | 0.4 | 8 | 8 | 365 nm | 60 |
| | ink 1 | | | | LED | |
| Example 29 | Conductive | 0.4 | 8 | 8 | 365 nm | 60 |
| | ink 1 | | | | LED | |
| Example 30 | Conductive | 0.4 | 8 | 8 | 365 nm | 60 |
| | ink 1 | | | | LED | |
| Example 31 | Conductive | 0.4 | 8 | 8 | 365 nm | 60 |
| | ink 1 | | | | LED | |
| Example 32 | Conductive | 0.4 | 8 | 8 | 365 nm | 60 |
| | ink 1 | | | | LED | |
| Example 33 | Conductive | 0.4 | 8 | 8 | 365 nm | 60 |
| | ink 1 | | | | LED | |
| Example 34 | Conductive | 1.6 | 2 | 2 | 365 nm | 45 |
| | nk 1 | | | | LED | |
| Example 35 | Conductive | 0.4 | 8 | 2 | 365 nm | 45 |
| | ink 1 | | | | LED | |
| Example 36 | Conductive | 0.4 | 8 | 1 | 365 nm | 45 |
| | ink 1 | | | | LED | |
| Comparative | Conductive | 0.4 | 8 | 8 | Pulse | 45 |
| Example 1 | ink 4 | | | | | |
| Comparative | Conductive | 0.4 | 10 | 10 | 365 nm | 60 |
| Example 2 | ink 1 | | | | LED | |
| Comparative | Conductive | 0.4 | 10 | 10 | 365 nm | 60 |
| Example 3 | ink 1 | | | | LED | |

| | How long | | Residual | | | |
|---|---|---|---|---|---|---|
| | it takes | Total | amount of | | | |
| | to start | exposure | liquid | | | |
| | exposure | amount | component | Image | | |
| | (sec) | (J/cm²) | (% by mass) | quality | Conductivity | Adhesiveness |
| Example 1 | 5.0 | 12 | 85 | 5 | 5 | 5 |
| Example 2 | 5.0 | 12 | 86 | 5 | 5 | 5 |
| Example 3 | 5.0 | 12 | 78 | 5 | 5 | 5 |
| Example 4 | 5.0 | 12 | 83 | 5 | 5 | 5 |
| Example 5 | 5.0 | 12 | 83 | 5 | 5 | 5 |
| Example 6 | 5.0 | 12 | 83 | 5 | 5 | 5 |
| Example 7 | 5.0 | 12 | 86 | 5 | 5 | 5 |
| Example 8 | 5.0 | 12 | 97 | 5 | 5 | 5 |
| Example 9 | 5.0 | 12 | 97 | 5 | 5 | 5 |
| Example 10 | 5.0 | 12 | 97 | 5 | 5 | 5 |
| Example 11 | 5.0 | 12 | 97 | 5 | 5 | 5 |
| Example 12 | 5.0 | 12 | 83 | 5 | 5 | 5 |
| Example 13 | 5.0 | 12 | 77 | 5 | 5 | 5 |
| Example 14 | 5.0 | 13 | 86 | 4 | 3 | 3 |
| Example 15 | 5.0 | 12 | 85 | 5 | 5 | 5 |
| Example 16 | 5.0 | 12 | 85 | 5 | 5 | 5 |
| Example 17 | 5.0 | 12 | 85 | 5 | 4 | 5 |
| Example 18 | 5.0 | 8 | 85 | 5 | 5 | 5 |
| Example 19 | 5.0 | 14 | 85 | 5 | 5 | 5 |
| Example 20 | 0.5 | 12 | 100 | 5 | 5 | 5 |
| Example 21 | 1.3 | 12 | 98 | 5 | 5 | 5 |
| Example 22 | 3.0 | 12 | 91 | 5 | 5 | 5 |
| Example 23 | 10.0 | 12 | 72 | 5 | 5 | 5 |
| Example 24 | 30.0 | 12 | 40 | 4 | 5 | 5 |
| Example 25 | 60.0 | 12 | 20 | 4 | 5 | 5 |
| Example 26 | 70.0 | 12 | 15 | 3 | 5 | 5 |
| Example 27 | 0.5 | 12 | 98 | 5 | 5 | 5 |
| Example 28 | 1.3 | 12 | 95 | 5 | 5 | 5 |
| Example 29 | 3.0 | 12 | 86 | 5 | 5 | 5 |
| Example 30 | 10.0 | 12 | 65 | 5 | 5 | 5 |
| Example 31 | 30.0 | 12 | 35 | 4 | 5 | 5 |
| Example 32 | 45.0 | 12 | 25 | 4 | 5 | 5 |
| Example 33 | 120.0 | 12 | 8 | 3 | 5 | 5 |
| Example 34 | 5.0 | 12 | 85 | 4 | 4 | 4 |
| Example 35 | 5.0 | 12 | 85 | 4 | 4 | 4 |
| Example 36 | 5.0 | 12 | 85 | 4 | 3 | 4 |
| Comparative | 1800 | 15 | 0 | 1 | 3 | 5 |
| Example 1 | | | | | | |
| Comparative | 1800 | 12 | 0 | 1 | 3 | 5 |
| Example 2 | | | | | | |
| Comparative | 600 | 12 | 2 | 1 | 3 | 3 |
| Example 3 | | | | | | |

As shown in Table 2, it has been found that an image having high image quality is obtained in Examples 1 to 36, because these examples include a step of applying a conductive ink onto a base material by using an ink jet recording method and a step of performing ultraviolet irradiation on the conductive ink applied onto the base material to form a conductive layer, and a content of a liquid component of the conductive ink at a time when the ultraviolet irradiation has begun is 5% by mass or more with respect to a content of the liquid component of the conductive ink at a time when the conductive ink has been applied onto the base material.

On the other hand, in Comparative Examples 1 to 3, the image quality of the obtained image was poor, because the content of a liquid component of the conductive ink at a time when ultraviolet irradiation has begun is less than 5% by mass with respect to the content of the liquid component of the conductive ink at a time when the conductive ink has been applied onto the base material.

It has been found that the conductive ink in Examples 1 to 13 contains a metal salt or a metal complex, and the image quality, conductivity, and adhesiveness in Examples 1 to 13 are better than those in Example 14 in which the conductive ink contains metal particles.

It has been found that In Example 25, the time from a time when the conductive ink has been landed on the base material to a time when the ultraviolet irradiation has begun is 60 seconds or less, and the image obtained in Example 25 has higher image quality compared to the image obtained in Example 26.

It has been found that In Example 23, the time from a time when the conductive ink has been landed on the base material to a time when the ultraviolet irradiation begins is 10 seconds or less, and the image obtained in Example 23 has higher image quality compared to the image obtained in Example 24.

It has been found that each conductive layer has an average thickness of 1.5 m or less in Example 1, and the image quality, conductivity, and adhesiveness in Example 1 are better than those in Example 34.

It has been found that because the ultraviolet irradiation is performed whenever the step of applying a conductive ink is carried out once In Example 1, the image quality, conductivity, and adhesiveness in Example 1 are better than those in Examples 35 and 36.

It has been found that the peak wavelength of the ultraviolet is 400 nm or less in Example 1, and the conductivity in Example 1 is better than that in Example 17.

TABLE 3

| | | | | | | | How | | | |
|---|---|---|---|---|---|---|---|---|---|---|
| | | Average | | | | | long it | | Residual | |
| | | thickness | Application | | | Temperature | takes to | Total | amount of | |
| | Type of | of each | of ink | Exposure | | of base | start | exposure | liquid | |
| | conductive | layer | (number | (number | Light | material | exposure | amount | component | Coating |
| | ink | (μm) | of times) | of times) | source | (° C.) | (sec) | (J/cm²) | (% by mass) | properties |
| Example 1 | Conductive | 0.4 | 8 | 8 | 365 nm | 45 | 5.0 | 12 | 85 | 3 |
| | ink 1 | | | | LED | | | | | |
| Example 20 | Conductive | 0.4 | 8 | 8 | 365 nm | 45 | 0.5 | 12 | 100 | 3 |
| | ink 1 | | | | LED | | | | | |
| Example 21 | Conductive | 0.4 | 8 | 8 | 365 nm | 45 | 1.3 | 12 | 98 | 3 |
| | ink 1 | | | | LED | | | | | |
| Example 22 | Conductive | 0.4 | 8 | 8 | 365 nm | 45 | 3.0 | 12 | 91 | 3 |
| | ink 1 | | | | LED | | | | | |
| Example 23 | Conductive | 0.4 | 8 | 8 | 365 nm | 45 | 10.0 | 12 | 72 | 3 |
| | ink 1 | | | | LED | | | | | |
| Example 24 | Conductive | 0.4 | 8 | 8 | 365 nm | 45 | 30.0 | 12 | 40 | 3 |
| | ink 1 | | | | LED | | | | | |

As shown in Table 3, it has been found that coating properties are excellent in Examples 1 and 20 to 24.

The entire disclosure of U.S. Patent App. No. 63/105,913, filed Oct. 27, 2020, is incorporated into the present specification by reference. In addition, all documents, patent applications, and technical standards described in the present specification are incorporated into the present specification by reference, as if each of the documents, the patent applications, and the technical standards is specifically and individually described.

What is claimed is:

1. An image recording method comprising:
applying a conductive ink onto a base material by using an ink jet recording method; and
performing ultraviolet irradiation on the conductive ink applied onto the base material to form a conductive layer,
wherein a content of a liquid component of the conductive ink at a time when the ultraviolet irradiation begins is 5% by mass or more with respect to a content of the liquid component of the conductive ink at a time when the conductive ink is applied onto the base material.

2. The image recording method according to claim 1,
wherein the conductive ink comprises a metal salt or a metal complex.

3. The image recording method according to claim 2,
wherein the metal complex has a structure derived from at least one compound selected from the group consisting of an ammonium carbamate compound, an ammonium carbonate compound, an amine, and a carboxylic acid having 8 to 20 carbon atoms, and
the metal salt is a metal carboxylate.

4. The image recording method according to claim 1,
wherein a time from a time when the conductive ink is landed on the base material to a time when the ultraviolet irradiation begins is 60 seconds or less.

5. The image recording method according to claim 1,
wherein a time from a time when the conductive ink is landed on the base material to a time when the ultraviolet irradiation begins is 10 seconds or less.

6. The image recording method according to claim 1,
wherein a lamination is performed one or more cycles, the lamination including applying a conductive ink onto the conductive layer by using an ink jet recording method and performing ultraviolet irradiation on the conductive ink applied onto the conductive layer to form a conductive layer, and
an average thickness of each conductive layer is 1.5 m or less.

7. The image recording method according to claim 6,
wherein the ultraviolet irradiation is performed whenever the applying a conductive ink is performed once.

8. The image recording method according to claim 1, further comprising:
applying an insulating ink onto a base material by using an ink jet recording method, a dispenser coating method, or a spray coating method and curing the insulating ink to form an insulating layer,
wherein the applying a conductive ink is applying a conductive ink onto the insulating layer.

9. The image recording method according to claim 1,
wherein the ultraviolet is light having a peak wavelength of 400 nm or less.

10. The image recording method according to claim 1,
wherein the base material is a base material for a print substrate.
